(19) United States
(12) Patent Application Publication
(10) Pub. No.: US 2026/0090080 A1
(43) Pub. Date: Mar. 26, 2026

(54) SEMICONDUCTOR DEVICE

(71) Applicant: Samsung Electronics Co., Ltd., Suwon-si (KR)

(72) Inventors: Dong Kwon KIM, Suwon-si (KR); Yeonghan GWON, Suwon-si (KR); Donghyun ROH, Suwon-si (KR); Chibeom PARK, Suwon-si (KR); Junsoo BAE, Suwon-si (KR); Hyoseok CHOI, Suwon-si (KR)

(73) Assignee: Samsung Electronics Co., Ltd., Suwon-si (KR)

(21) Appl. No.: 19/071,114

(22) Filed: Mar. 5, 2025

(30) Foreign Application Priority Data
Sep. 26, 2024 (KR) 10-2024-0131025

(51) Int. Cl. H10D 84/83; H10D 30/00; H10D 30/01; H10D 62/10; H10D 62/13; H10D 64/23; H10D 84/01

(52) U.S. Cl. CPC H10D 84/833; H10D 30/503; H10D 62/121; H10D 62/151; H10D 64/256; H10D 30/019; H10D 84/013; H10D 84/0151

(57) ABSTRACT

A semiconductor device including a first fin pattern and a second fin pattern, a first source/drain pattern overlapping the first fin pattern, a second source/drain pattern overlapping the second fin pattern, a lower separation dielectric layer between the first and second fin patterns and between the first and second source/drain patterns, a cover dielectric layer on the first source/drain pattern and the second source/drain pattern, and an upper separation dielectric layer overlapping the lower separation dielectric layer may be provided. A lower portion of the upper separation dielectric layer may be between the first source/drain pattern and the second source/drain pattern. An upper portion of the upper separation dielectric layer may be at a level higher than a level of the cover dielectric layer.

### CROSS-REFERENCE TO RELATED APPLICATION

This application claims priority under 35 U.S.C § 119 to Korean Patent Application No. 10-2024-0131025 filed on Sep. 26, 2024 in the Korean Intellectual Property Office, the disclosure of which is hereby incorporated by reference in its entirety.

### BACKGROUND

The present inventive concepts relate to semiconductor devices, and more particularly, to semiconductor devices including an upper separation dielectric layer.

A semiconductor device includes an integrated circuit consisting of or made up of metal oxide semiconductor field effect transistors (MOSFETs). As size and design rule of the semiconductor device are gradually decreased, sizes of the MOSFETs are also increasingly scaled down. The scale down of MOSFETs may deteriorate operating characteristics of the semiconductor device. Accordingly, research has been variously developed to manufacture the semiconductor device having improved performances while overcoming limitations caused by higher integration of the semiconductor device.

### SUMMARY

Some example embodiments of the present inventive concepts provide semiconductor devices with increased reliability and/or improved electrical properties.

According to an example embodiment of the present inventive concepts, a semiconductor device may include a first fin pattern and a second fin pattern, a first source/drain pattern overlapping the first fin pattern, a second source/drain pattern overlapping the second fin pattern, a lower separation dielectric layer between the first and second fin patterns and between the first and second source/drain patterns, a cover dielectric layer on the first source/drain pattern and the second source/drain pattern, and an upper separation dielectric layer overlapping the lower separation dielectric layer. A lower portion of the upper separation dielectric layer may be between the first source/drain pattern and the second source/drain pattern. An upper portion of the upper separation dielectric layer may be at a level higher than a level of the cover dielectric layer.

According to an example embodiment of the present inventive concepts, a semiconductor device may include a first fin pattern and a second fin pattern, a first source/drain pattern overlapping the first fin pattern, a second source/drain pattern overlapping the second fin pattern, a first lower separation dielectric layer between the first and second fin patterns and between the first and second source/drain patterns, a cover dielectric layer on the first source/drain pattern and the second source/drain pattern, an interlayer dielectric layer on the cover dielectric layer, and an upper separation dielectric layer overlapping the first lower separation dielectric layer. A lower portion of the upper separation dielectric layer may be between the first source/drain pattern and the second source/drain pattern. A sidewall of an upper portion of the upper separation dielectric layer may be in contact with the interlayer dielectric layer.

According to an example embodiment of the present inventive concepts, a semiconductor device may include a first fin pattern and a second fin pattern, a plurality of first semiconductor patterns overlapping the first fin pattern, a plurality of second semiconductor patterns overlapping the second fin pattern, a first source/drain pattern connected to the first semiconductor patterns, a second source/drain pattern connected to the second semiconductor patterns, a gate electrode overlapping the first semiconductor patterns, a first lower separation dielectric layer between the first and second fin patterns, between the first and second semiconductor patterns, and between the first and second source/drain patterns, a first upper separation dielectric layer overlapping the first lower separation dielectric layer, an active contact connected to the second source/drain pattern, a third fin pattern and a fourth fin pattern spaced apart from the first and second fin patterns, a plurality of third semiconductor patterns overlapping the third fin pattern, a plurality of fourth semiconductor patterns overlapping the fourth fin pattern, a second lower separation dielectric layer between the third and fourth fin patterns and between the third and fourth semiconductor patterns, a merge active contact overlapping the second lower separation dielectric layer, the third fin pattern, and the fourth fin pattern, a second upper separation dielectric layer between the merge active contact and the active contact, a cover dielectric layer in contact with the active contact, the merge active contact, and the first and second source/drain patterns, and an interlayer dielectric layer on the cover dielectric layer. An upper portion of the first upper separation dielectric layer may have a sidewall spaced apart from the cover dielectric layer.

### BRIEF DESCRIPTION OF DRAWINGS

FIG. 1A illustrates a plan view showing a semiconductor device according to an example embodiment.

FIG. 1B illustrates a cross-sectional view taken along line A-A′ of FIG. 1A.

FIG. 1C illustrates a cross-sectional view taken along line B-B′ of FIG. 1A.

FIG. 1D illustrates a cross-sectional view taken along line C-C′ of FIG. 1A.

FIG. 1E illustrates an enlarged view showing section Q1 of FIG. 1B.

FIG. 1F illustrates an enlarged view showing section Q2 of FIG. 1B.

FIGS. 2, 3, 4A, 4B, 5, 6, 7, 8, 9, 10A, 10B, and 11 illustrate cross-sectional views showing a method of fabricating a semiconductor device according to FIGS. 1A to 1F.

FIG. 12A illustrates a cross-sectional view showing a semiconductor device according to an example embodiment.

FIG. 12B illustrates an enlarged view showing section Q3 of FIG. 12A.

FIG. 12C illustrates an enlarged view showing section Q4 of FIG. 12A.

FIGS. 13, 14, 15, and 16 illustrate cross-sectional views showing a method of fabricating a semiconductor device according to FIGS. 12A to 12C.

FIG. 17A illustrates a cross-sectional view showing a semiconductor device according to an example embodiment.

FIG. 17B illustrates an enlarged view showing section Q5 of FIG. 17A.

FIG. 17C illustrates an enlarged view showing section Q6 of FIG. 17A.

FIGS. 18, 19, and 20 illustrate cross-sectional views showing a method of fabricating a semiconductor device according to FIGS. 17A to 17C.

FIG. 21 illustrates a cross-sectional view showing a semiconductor device according to an example embodiment.

### DETAILED DESCRIPTION

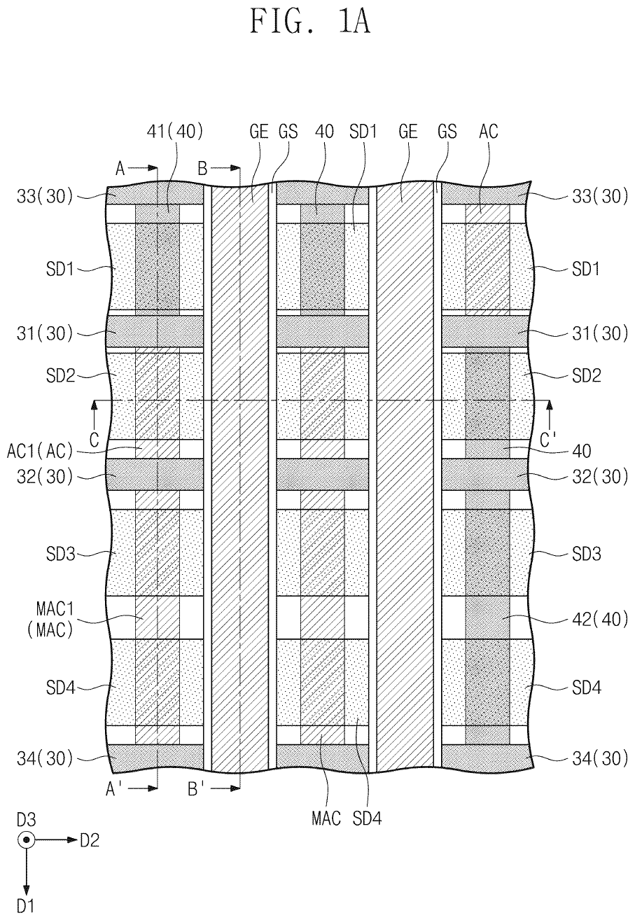

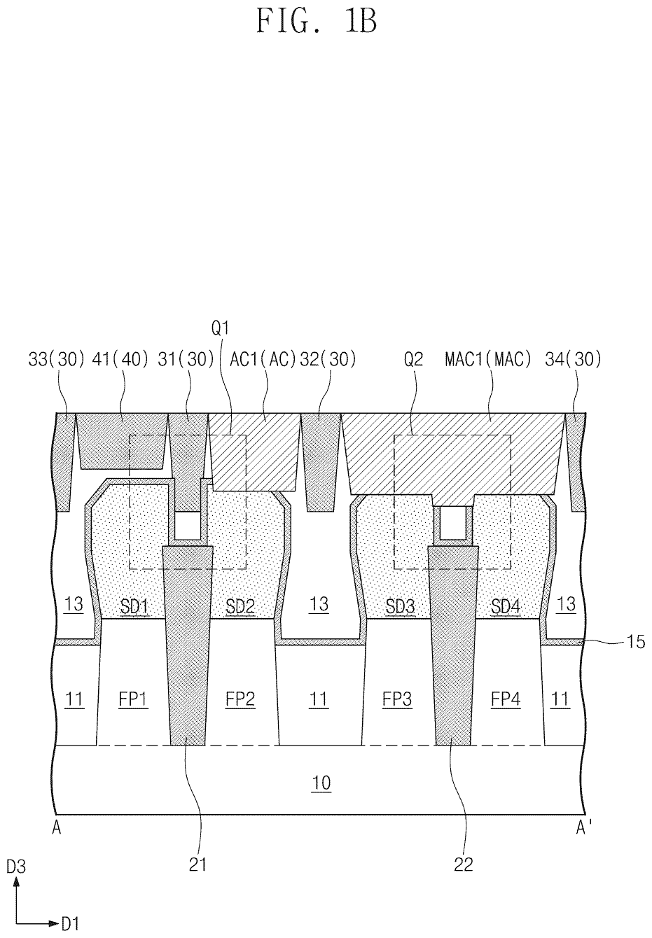

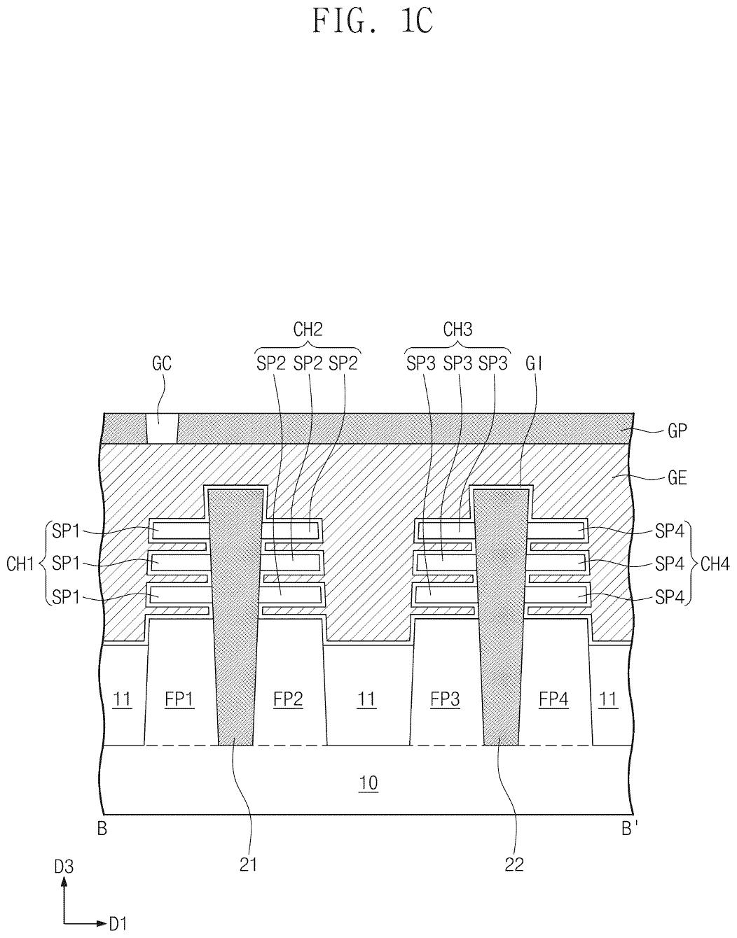

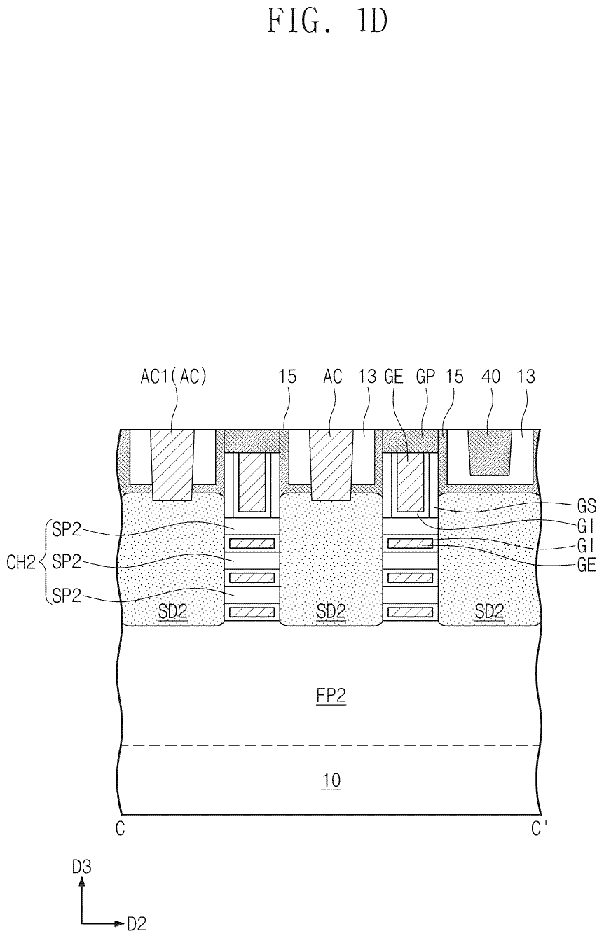

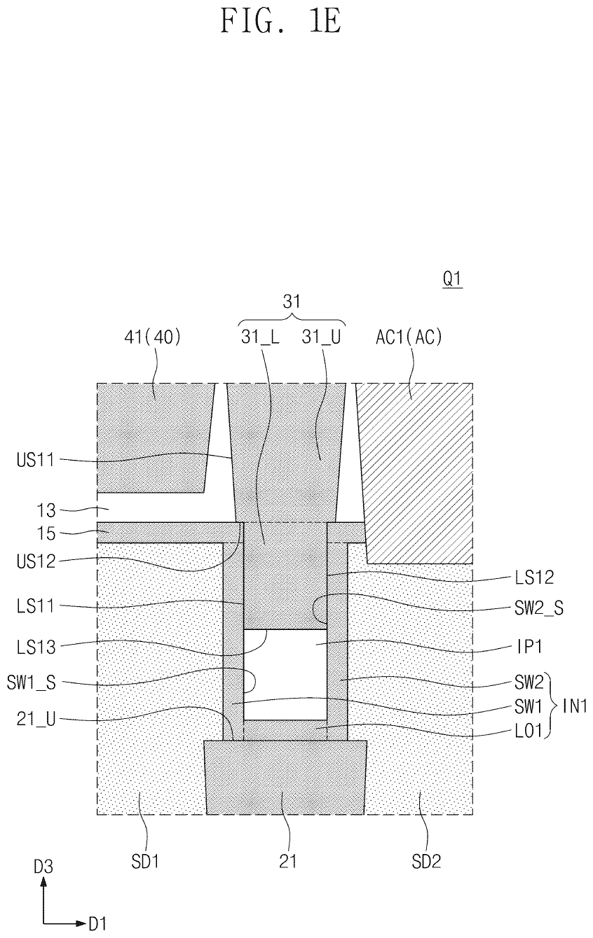

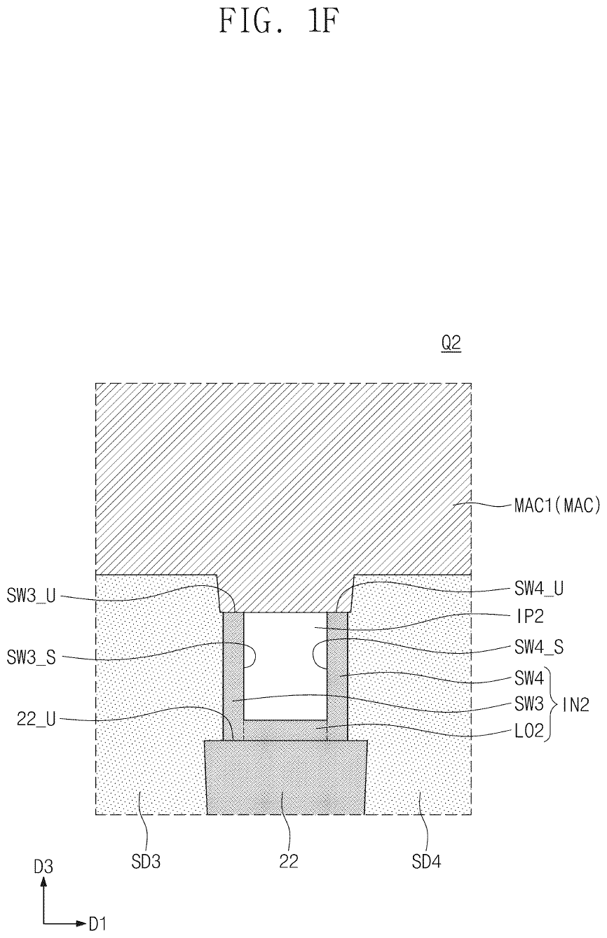

FIG. 1A illustrates a plan view showing a semiconductor device according to an example embodiment. FIG. 1B illustrates a cross-sectional view taken along line A-A′ of FIG. 1A. FIG. 1C illustrates a cross-sectional view taken along line B-B′ of FIG. 1A. FIG. 1D illustrates a cross-sectional view taken along line C-C′ of FIG. 1A. FIG. 1E illustrates an enlarged view showing section Q1 of FIG. 1B. FIG. 1F illustrates an enlarged view showing section Q2 of FIG. 1B.

Referring to FIGS. 1A, 1B, 1C, and 1D, a semiconductor device may include a substrate 10. The substrate 10 may be provided thereon with logic transistors included in a logic circuit. The substrate 10 may be a semiconductor substrate, a dielectric substrate, or a semiconductor-on-insulator (SOI) substrate. The semiconductor substrate may include, for example, silicon (Si), germanium (Ge), silicon-germanium (SiGe), gallium-phosphorus (GaP), or gallium-arsenic (GaAs).

The substrate 10 may have a plate shape elongated along a plane defined in a first direction D1 and a second direction D2. The first direction D1 and the second direction D2 may intersect each other. For example, the first direction D1 and the second direction D2 may be horizontal directions that are orthogonal to each other.

The substrate 10 may include a first fin pattern FP1, a second fin pattern FP2, a third fin pattern FP3, and a fourth fin pattern FP4. The first, second, third, and fourth fin patterns FP1, FP2, FP3, and FP4 may extend in the second direction D2. The first, second, third, and fourth fin patterns FP1, FP2, FP3, and FP4 may be arranged spaced apart from each other in the first direction D1. The first, second, third, and fourth fin patterns FP1, FP2, FP3, and FP4 may be upper portions of the substrate 10 that protrude in a third direction D3. The third direction D3 may intersect the first direction D1 and the second direction D2. For example, the third direction D3 may be a vertical direction perpendicular to the first direction D1 and the second direction D2.

In some example embodiments, the substrate 10 may not include a lower portion that connects the fin patterns FP1, FP2, FP3, and FP4 to each other, and the fin patterns FP1, FP2, FP3, and FP4 may be separated from each other. In some example embodiments, the separated fin patterns FP1, FP2, FP3, and FP4 may include a dielectric material.

A device isolation layer 11 may be provided on the substrate 10. The fin patterns FP1, FP2, FP3, and FP4 may be disposed between portions of the device isolation layer 11. The device isolation layer 11 may include a dielectric material. For example, the device isolation layer 11 may include oxide.

First channel structures CH1 may be provided to overlap in the third direction D3 the first fin pattern FP1, second channel structures CH2 may be provided to overlap in the third direction D3 the second fin pattern FP2, third channel structures CH3 may be provided to overlap in the third direction D3 the third fin pattern FP3, and fourth channel structures CH4 may be provided to overlap in the third direction D3 the fourth fin pattern FP4. The first channel structures CH1 may be arranged spaced apart from each other in the second direction D2.

The first channel structure CH1 may include first semiconductor patterns SP1 that are arranged spaced apart from each other in the third direction D3. The first semiconductor patterns SP1 may overlap each other in the third direction D3. The second channel structure CH2 may include second semiconductor patterns SP2 that are arranged spaced apart from each other in the third direction D3. The third channel structure CH3 may include third semiconductor patterns SP3 that are arranged spaced apart from each other in the third direction D3. The fourth channel structure CH4 may include fourth semiconductor patterns SP4 that are arranged spaced apart from each other in the third direction D3.

The number of the semiconductor patterns SP1, SP2, SP3, or SP4 included in one channel structure CH1, CH2, CH3, or CH4 may not be limited to that shown. In some example embodiments, the number of the semiconductor patterns SP1, SP2, SP3, or SP4 included in one channel structure CH1, CH2, CH3, or CH4 may be equal to or less than 2 or equal to or greater than 4.

In some example embodiments, the semiconductor patterns SP1, SP2, SP3, and SP4 may include silicon (Si). For example, the semiconductor patterns SP1, SP2, SP3, and SP4 may include crystalline silicon.

First source/drain patterns SD1 may overlap in the third direction D3 the first fin pattern FP1, second source/drain patterns SD2 may overlap in the third direction D3 the second fin pattern FP2, third source/drain patterns SD3 may overlap in the third direction D3 the third fin pattern FP3, and fourth source/drain patterns SD4 may overlap in the third direction D3 the fourth fin pattern FP4.

The first source/drain patterns SD1 may be arranged spaced apart from each other in the second direction D2. The first source/drain pattern SD1 may be connected to the first semiconductor patterns SP1. The first source/drain pattern SD1 may be in contact with the first semiconductor patterns SP1. The second source/drain pattern SD2 may be connected to the second semiconductor patterns SP2. The third source/drain pattern SD3 may be connected to the third semiconductor patterns SP3. The fourth source/drain pattern SD4 may be connected to the fourth semiconductor patterns SP4.

The source/drain patterns SD1, SD2, SD3, and SD4 may be epitaxial patterns formed by a selective epitaxial growth process. The source/drain patterns SD1, SD2, SD3, and SD4 may include, for example, silicon (Si) or silicon-germanium (SiGe). In some example embodiments, the first and second source/drain patterns SD1 and SD2 may have their conductivity type different from that of the third and fourth source/drain patterns SD3 and SD4. For example, the first and second source/drain patterns SD1 and SD2 may have an n-type conductivity, and the third and fourth source/drain patterns SD3 and SD4 may have a p-type conductivity.

A first lower separation dielectric layer 21 and a second lower separation dielectric layer 22 may be provided. The first lower separation dielectric layer 21 and the second lower separation dielectric layer 22 may extend in the second direction D2. The first lower separation dielectric layer 21 and the second lower separation dielectric layer 22 may be spaced apart from each other in the first direction D1.

The first lower separation dielectric layer 21 may be disposed between the first and second fin patterns FP1 and FP2, between the first and second source/drain patterns SD1 and SD2, and between the first and second semiconductor patterns SP1 and SP2. The second lower separation dielectric layer 22 may be disposed between the third and fourth fin patterns FP3 and FP4, between the third and fourth source/drain patterns SD3 and SD4, and between the third and fourth semiconductor patterns SP3 and SP4.

Each of the first and second lower separation dielectric layers 21 and 22 may include a first portion disposed between the source/drain patterns SD1, SD2, SD3, and SD4 and a second portion disposed between the semiconductor patterns SP1, SP2, SP3, and SP4. The first portion, which is disposed between the source/drain patterns SD1, SD2, SD3, and SD4, of each of the first and second lower separation dielectric layers 21 and 22 may have a top surface at a level lower than that of the second portion, which is disposed between the semiconductor patterns SP1, SP2, SP3, and SP4, of each of the first and second lower separation dielectric layers 21 and 22.

The first and second lower separation dielectric layers 21 and 22 may include a dielectric material. For example, the first and second lower separation dielectric layers 21 and 22 may include nitride.

Gate electrodes GE may be provided. The gate electrodes GE may extend in the first direction D1. The gate electrode GE may overlap in the third direction D3 the semiconductor patterns SP1, SP2, SP3, and SP4. The gate electrode GE and the semiconductor patterns SP1, SP2, SP3, and SP4 may constitute a three-dimensional field effect transistor (e.g., Multi-Bridge Channel Field-Effect Transistor (MBCFET) or Gate-All-Around Field-Effect Transistor (GAAFET)). The gate electrode GE may include a conductive material. In some example embodiments, the gate electrode GE may include a barrier layer and a conductive layer including different materials from each other.

Gate dielectric layers GI may be provided. The gate dielectric layer GI may separate the gate electrode GE from the semiconductor patterns SP1, SP2, SP3, and SP4. The gate dielectric layer GI may be provided between the gate electrode GE and the semiconductor patterns SP1, SP2, SP3, and SP4. The gate dielectric layer GI may separate the gate electrode GE from the lower separation dielectric layers 21 and 22. The gate dielectric layer GI may be provided between the gate electrode GE and the lower separation dielectric layers 21 and 22. The gate dielectric layer GI may be in contact with the semiconductor patterns SP1, SP2, SP3, and SP4, the device isolation layer 11, and the lower separation dielectric layers 21 and 22. The gate dielectric layer GI may include a dielectric material. For example, the gate dielectric layer GI may include oxide.

Gate spacers GS may be provided. The gate spacers GS may be disposed on opposite sides of the gate electrode GE. The gate spacers GS may include a dielectric material.

Gate capping patterns GP may be provided. The gate capping pattern GP may be provided on the gate electrode GE. The gate capping pattern GP may include a dielectric material. For example, the gate capping pattern GP may include nitride.

In some example embodiments, a gate cutting dielectric layer may be provided to separate the gate electrodes GE from each other in the first direction D1.

A cover dielectric layer 15 may be provided. The cover dielectric layer 15 may be provided on the device isolation layer 11, the source/drain patterns SD1, SD2, SD3, and SD4, and the gate spacer GS. The cover dielectric layer 15 may be in contact with the device isolation layer 11, the source/drain patterns SD1, SD2, SD3, and SD4, and the gate spacer GS. The cover dielectric layer 15 may include a dielectric material. For example, the cover dielectric layer 15 may include nitride. In some example embodiments, the cover dielectric layer 15 may include a dielectric material different from that of the lower separation dielectric layers 21 and 22 and that of an upper separation dielectric layer 30 which will be discussed below. For example, the lower separation dielectric layers 21 and 22 and the upper separation dielectric layer 30 may include SiN, and the cover dielectric layer 15 may include SiCN.

An interlayer dielectric layer 13 may be provided on the cover dielectric layer 15. The interlayer dielectric layer 13 may be spaced apart from the source/drain patterns SD1, SD2, SD3, and SD4. The cover dielectric layer 15 may be provided between the interlayer dielectric layer 13 and the source/drain patterns SD1, SD2, SD3, and SD4. The interlayer dielectric layer 13 may be in contact with the cover dielectric layer 15. The interlayer dielectric layer 13 may include a dielectric material. For example, the interlayer dielectric layer 13 may include oxide.

Upper separation dielectric layers 30 may be provided. The upper separation dielectric layers 30 may include first upper separation dielectric layers 31 that overlap in the third direction D3 the first lower separation dielectric layer 21, second upper separation dielectric layers 32 disposed between the second and third source/drain patterns SD2 and SD3, and third upper separation dielectric layers 33 and fourth upper separation dielectric layers 34 that are spaced apart in the first direction D1 from each other across the first and second upper separation dielectric layers 31 and 32.

The first and second source/drain patterns SD1 and SD2 may be provided between the second and third upper separation dielectric layers 32 and 33. The third and fourth source/drain patterns SD3 and SD4 may be provided between the second and fourth upper separation dielectric layers 32 and 34. The first upper separation dielectric layers 31 may be provided between the first and second source/drain patterns SD1 and SD2.

The upper separation dielectric layers 30 may be provided on the interlayer dielectric layer 13. The upper separation dielectric layers 30 may be in contact with the interlayer dielectric layer 13. The first upper separation dielectric layer 31 may be in contact with the cover dielectric layer 15.

A distance in the first direction D1 between the first and third upper separation dielectric layers 31 and 33 and a distance in the first direction D1 between the first and second upper separation dielectric layers 31 and 32 may be less than a distance in the first direction D1 between the second and fourth upper separation dielectric layers 32 and 34. The upper separation dielectric layer 30 may include a dielectric material. For example, the upper separation dielectric layers 30 may include nitride.

Active contacts AC may be provided. The active contact AC may include a first active contact AC1 that is connected to the second source/drain pattern SD2 and is disposed between the first and second upper separation dielectric layers 31 and 32. The first active contact AC1 may be in contact with the second source/drain pattern SD2. The first active contact AC1 may be in contact with the cover dielectric layer 15. The active contact AC may include a conductive material.

Merge active contacts MAC may be provided. The merge active contacts MAC may include a first merge active contact MAC1 that is in contact with the third and fourth source/drain patterns SD3 and SD4 and is disposed between the second and fourth upper separation dielectric layers 32 and 34. The first merge active contact MAC1 may overlap in the third direction D3 the third fin pattern FP3, the fourth fin pattern FP4, and the second lower separation dielectric layer 22. The second upper separation dielectric layer 32 may be disposed between the first merge active contact MAC1 and the first active contact AC1.

The merge active contact MAC may include a conductive material. A length in the first direction D1 of the active contact AC may be less than a length in the first direction D1 of the merge active contact MAC.

Filling patterns 40 may be provided. The filling pattern 40 may overlap in the third direction D3 each of the source/drain patterns SD1, SD2, SD3, and SD4. The filling patterns 40 may be provided on the interlayer dielectric layer 13. The filling patterns 40 may include a first filling pattern 41 that overlaps in the third direction D3 the first source/drain pattern SD1 and is disposed between the first and third upper separation dielectric layers 31 and 33. The filling patterns 40 may include a second filling pattern 42 that overlaps in the third direction D3 the third and fourth source/drain patterns SD3 and SD4 and is disposed between the second and fourth upper separation dielectric layers 32 and 34.

A length in the first direction D1 of the first filling pattern 41 may be less than a length in the first direction D1 of the second filling pattern 42. The filling patterns 40 may include a dielectric material. For example, the filling patterns 40 may include nitride.

A gate contact GC may be provided. The gate contact GC may penetrate the gate capping pattern GP. The gate contact GC may be connected to the gate electrode GE. The gate contact GC may include a conductive material.

Referring to FIG. 1E, the first upper separation dielectric layer 31 may include a lower portion 31_L and an upper portion 31_U. The lower portion 31_L of the first upper separation dielectric layer 31 may be located at a level lower than that of an uppermost portion of the cover dielectric layer 15. The upper portion 31_U of the first upper separation dielectric layer 31 may be located at a level higher than that of the uppermost portion of the cover dielectric layer 15. The upper portion 31_U of the first upper separation dielectric layer 31 may be located at a level higher than that of uppermost portions of the first and second source/drain patterns SD1 and SD2. The first upper separation dielectric layer 31 may be spaced apart from the first and second source/drain patterns SD1 and SD2.

The cover dielectric layer 15 may include a first intervention IN1 between the first source/drain pattern SD1 and the second source/drain pattern SD2. The first intervention IN1 may include a first sidewall portion SW1 in contact with the first source/drain pattern SD1, a second sidewall portion SW2 in contact with the second source/drain pattern SD2, and a lower portion LO1 that connects the first sidewall portion SW1 and the second sidewall portion SW2 to each other. The lower portion LO1 of the first intervention IN1 may be disposed between the first sidewall portion SW1 and the second sidewall portion SW2 of the first intervention IN1.

The lower portion LO1 of the first intervention IN1 may be in contact with a top surface 21_U of the first lower separation dielectric layer 21. The first sidewall portion SW1 of the first intervention IN1 may be provided between the first source/drain pattern SD1 and the lower portion 31_L of the first upper separation dielectric layer 31. The second sidewall portion SW2 of the first intervention IN1 may be provided between the second source/drain pattern SD2 and the lower portion 31_L of the first upper separation dielectric layer 31.

The lower portion 31_L of the first upper separation dielectric layer 31 may be disposed between the first source/drain pattern SD1 and the second source/drain pattern SD2. The lower portion 31_L of the first upper separation dielectric layer 31 may be disposed between the first sidewall portion SW1 and the second sidewall portion SW2 of the first intervention IN1. The lower portion 31_L of the first upper separation dielectric layer 31 may include a first sidewall LS11 in contact with a sidewall SW1_S of the first sidewall portion SW1 included in the first intervention IN1, and may also include a second sidewall LS12 in contact with a sidewall SW2_S of the second sidewall portion SW2 included in the first intervention IN1. For the lower portion 31_L of the first upper separation dielectric layer 31, the first sidewall LS11 and the second sidewall LS12 may stand opposite to each other.

The lower portion 31_L of the first upper separation dielectric layer 31 may have a bottom surface LS13 spaced apart from the cover dielectric layer 15. The lower portion 31_L of the first upper separation dielectric layer 31 may have a bottom surface LS13 that faces a top surface of the lower portion LO1 of the first intervention IN1.

The upper portion 31_U of the first upper separation dielectric layer 31 may have a sidewall US11 spaced apart from the cover dielectric layer 15. The sidewall US11 of the upper portion 31_U of the first upper separation dielectric layer 31 may be in contact with the interlayer dielectric layer 13. The sidewall US11 of the upper portion 31_U of the first upper separation dielectric layer 31 may be located at a level higher than that of the uppermost portion of the cover dielectric layer 15. The upper portion 31_U of the first upper separation dielectric layer 31 may include a surface US12 that connects the sidewall US11 of the upper portion 31_U of the first upper separation dielectric layer 31 to the sidewalls LS11 and LS12 of the lower portion 31_L of the first upper separation dielectric layer 31. The surface US12 of the upper portion 31_U of the first upper separation dielectric layer 31 may be in contact with the cover dielectric layer 15.

A minimum width in the first direction D1 of the upper portion 31_U of the first upper separation dielectric layer 31 may be greater than a maximum width in the first direction D1 of the lower portion 31_L of the first upper separation dielectric layer 31.

The interlayer dielectric layer 13 may include a first dielectric pattern IP1 between the top surface 21_U of the first lower separation dielectric layer 21 and the bottom surface LS13 of the lower portion 31_L of the first upper separation dielectric layer 31. The first dielectric pattern IP1 may be disposed between the first sidewall portion SW1 and the second sidewall portion SW2 of the first intervention IN1. The first dielectric pattern IP1 may be disposed between the lower portion LO1 of the first intervention IN1 and the bottom surface LS13 of the lower portion 31_L of the first upper separation dielectric layer 31. The first dielectric pattern IP1 may be disposed between the first and second source/drain patterns SD1 and SD2.

The first dielectric pattern IP1 may be in contact with the sidewall SW1_S of the first sidewall portion SW1 of the first intervention IN1, the sidewall SW2_S of the second sidewall portion SW2 of the first intervention IN1, the top surface of the lower portion LO1 of the first intervention IN1, and the bottom surface LS13 of the lower portion 31_L of the first upper separation dielectric layer 31.

In some example embodiments, an air gap may be provided between the first sidewall portion SW1 and the second sidewall portion SW2 of the first intervention IN1 and between the lower portion 31_L of the first upper separation dielectric layer 31 and the lower portion LO1 of the first intervention IN1. The air gap may be provided between the lower portion 31_L of the first upper separation dielectric layer 31 and the first lower separation dielectric layer 21.

Referring to FIG. 1F, the cover dielectric layer 15 may include a second intervention IN2 between the third source/drain pattern SD3 and the fourth source/drain pattern SD4. The second intervention IN2 may include a third sidewall portion SW3 in contact with the third source/drain pattern SD3, a fourth sidewall portion SW4 in contact with the fourth source/drain pattern SD4, and a lower portion LO2 that connects the third sidewall portion SW3 and the fourth sidewall portion SW4 to each other. The lower portion LO2 of the second intervention IN2 may be disposed between the third sidewall portion SW3 and the fourth sidewall portion SW4 of the second intervention IN2.

The lower portion LO2 of the second intervention IN2 may be in contact with a top surface 22_U of the second lower separation dielectric layer 22. The second intervention IN2 may be provided between the first merge active contact MAC1 and the second lower separation dielectric layer 22.

The interlayer dielectric layer 13 may include a second dielectric pattern IP2 between the first merge active contact MAC1 and the top surface 22_U of the second lower separation dielectric layer 22. The second dielectric pattern IP2 may be disposed between the third sidewall portion SW3 and the fourth sidewall portion SW4 of the second intervention IN2. The second dielectric pattern IP2 may be disposed between the first merge active contact MAC1 and the lower portion LO2 of the second intervention IN2. The second dielectric pattern IP2 may be disposed between the third and fourth source/drain patterns SD3 and SD4.

The second dielectric pattern IP2 may be in contact with a sidewall SW3_S of the third sidewall portion SW3 of the second intervention IN2, a sidewall SW4_S of the fourth sidewall portion SW4 of the second intervention IN2, a top surface of the lower portion LO2 of the second intervention IN2, and the first merge active contact MAC1.

The first merge active contact MAC1 may be in contact with cover dielectric layer 15. The first merge active contact MAC1 may be in contact with a top surface SW3_U of the third sidewall portion SW3 of the second intervention IN2 and a top surface SW4_U of the fourth sidewall portion SW4 of the second intervention IN2.

In some example embodiments, an air gap may be provided between the third sidewall portion SW3 and the fourth sidewall portion SW4 and between the first merge active contact MAC1 and the lower portion LO2 of the second intervention IN2. The air gap may be provided between the first merge active contact MAC1 and the second lower separation dielectric layer 22.

In the semiconductor device according to some example embodiments, an air gap may be provided between source/drain patterns, and the air gap may cause an effect of capacitance reduction.

In the semiconductor device according to some example embodiments, an upper separation dielectric layer may not be disposed between source/drain patterns connected to the merge active contact MAC, and thus there may be a reduction in contact resistance of the merge active contact MAC.

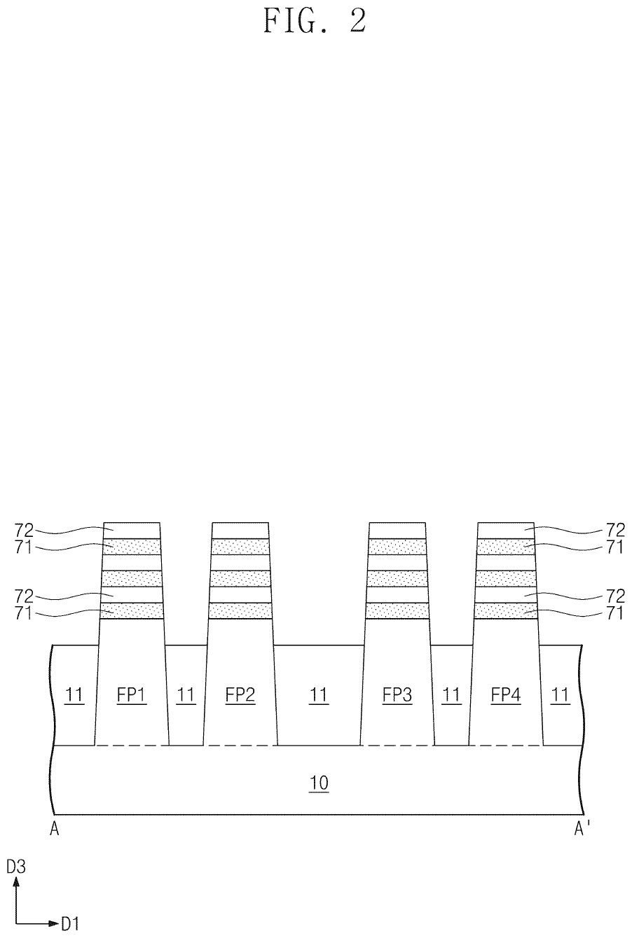

FIGS. 2, 3, 4A, 4B, 5, 6, 7, 8, 9, 10A, 10B, and 11 illustrate cross-sectional views showing a method of fabricating a semiconductor device according to FIGS. 1A to 1F.

Referring to FIG. 2, fin patterns FP1, FP2, FP3, and FP4, sacrificial semiconductor layers 71, and semiconductor layers 72 may be formed.

The formation of the fin patterns FP1, FP2, FP3, and FP4, the sacrificial semiconductor layers 71, and the semiconductor layers 72 may include alternately forming preliminary sacrificial semiconductor layers and preliminary semiconductor layers on a substrate 10, and patterning the substrate 10, the preliminary sacrificial semiconductor layers, and the preliminary semiconductor layers to form the fin patterns FP1, FP2, FP3, and FP4, the sacrificial semiconductor layers 71, and the semiconductor layers 72.

The sacrificial semiconductor layer 71 may include a material having an etch selectivity with respect to the semiconductor layer 72. For example, the sacrificial semiconductor layer 71 may include silicon-germanium (SiGe), and the semiconductor layer 72 may include silicon (Si).

A device isolation layer 11 may be formed.

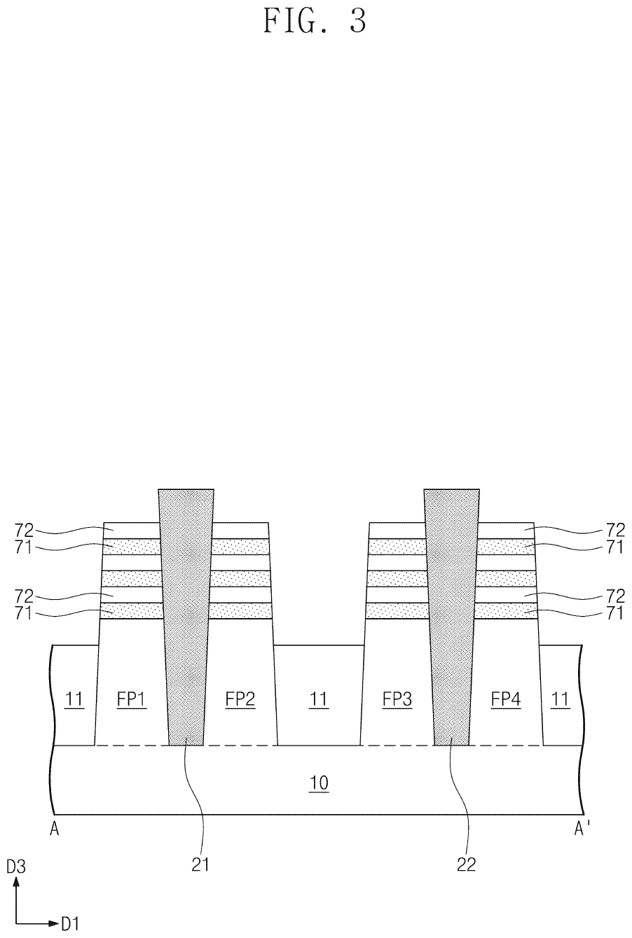

Referring to FIG. 3, first and second lower separation dielectric layers 21 and 22 may be formed. In some example embodiments, the formation of the first and second lower separation dielectric layers 21 and 22 may include removing a portion of the device isolation layer 11 between the first and second fin patterns FP1 and FP2 and a portion of the device isolation layer 11 between the third and fourth fin patterns FP3 and FP4, forming a preliminary dielectric layer, and etching the preliminary dielectric layer to form the first and second lower separation dielectric layers 21 and 22.

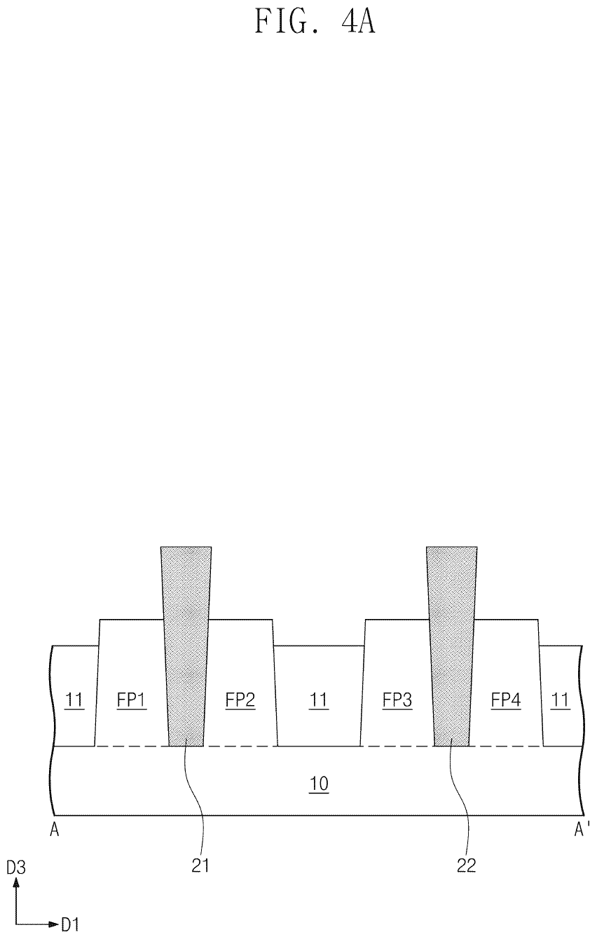

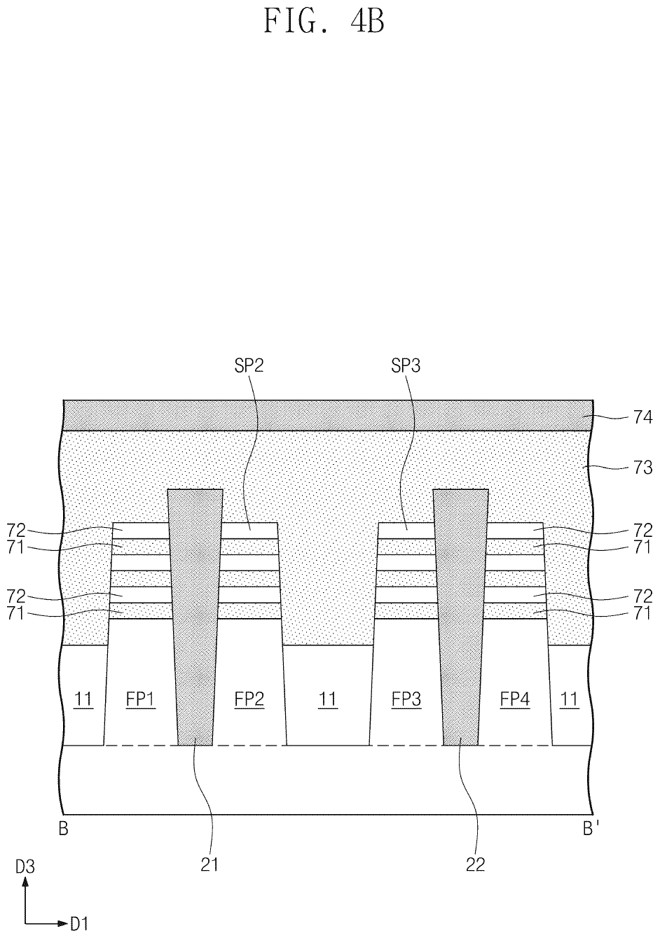

Referring to FIGS. 4A and 4B, gate sacrificial patterns 73, gate mask patterns 74, and gate spacers may be formed (see GS of FIGS. 1A and 1D). The formation of the gate sacrificial patterns 73, the gate mask patterns 74, and the gate spacers GS may include forming a preliminary gate sacrificial layer on the first and second lower separation dielectric layers 21 and 22, the semiconductor layers 72, and the sacrificial semiconductor layers 71, forming the gate mask pattern 74 on the preliminary gate sacrificial layer, using the gate mask pattern 74 as an etching mask to etch the preliminary gate sacrificial layer to form the gate sacrificial pattern 73, and forming the gate spacers GS.

The gate sacrificial pattern 73 and the gate mask pattern 74 may extend in a first direction D1. The gate sacrificial pattern 73 may include, for example, polysilicon. The gate mask pattern 74 may include a dielectric material. For example, the gate mask pattern 74 may include nitride.

The gate mask pattern 74 and the gate spacer GS may be used as an etching mask to etch the first and second lower separation dielectric layers 21 and 22, the sacrificial semiconductor layers 71, and the semiconductor layers 72. The semiconductor layer 72 may be etched into semiconductor patterns SP1, SP2, SP3, and SP4.

Portions of the first and second lower separation dielectric layers 21 and 22 that do not overlap in a third direction D3 the gate sacrificial pattern 73 may be etched.

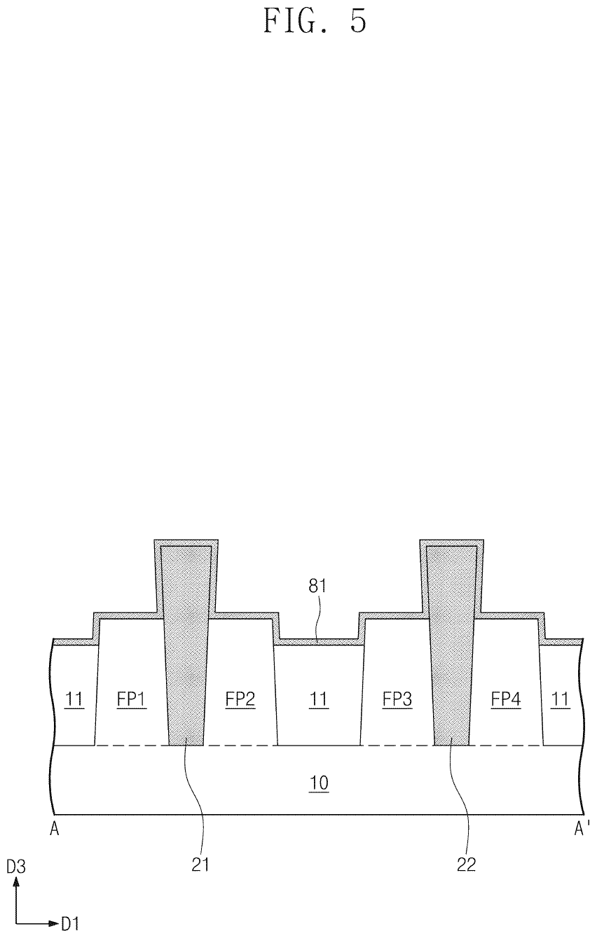

Referring to FIG. 5, a first liner 81 may be formed. The first liner 81 may be formed on the device isolation layer 11, the fin patterns FP1, FP2, FP3, and FP4, and the lower separation dielectric layers 21 and 22. The first liner 81 may include a dielectric material. For example, the first liner 81 may include nitride (e.g., SiCN).

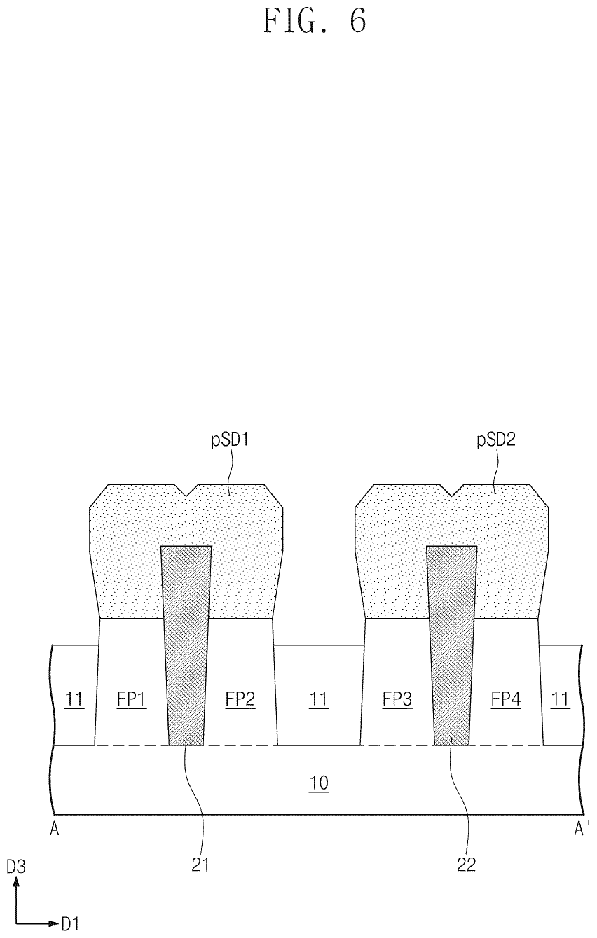

Referring to FIG. 6, a first preliminary source/drain pattern pSD1 and a second preliminary source/drain pattern pSD2 may be formed. The first preliminary source/drain pattern pSD1 and the second preliminary source/drain pattern pSD2 may be formed through a selective epitaxial growth process. The first liner 81 may be removed during the formation of the first preliminary source/drain pattern pSD1 and the second preliminary source/drain pattern pSD2.

In some example embodiments, the first preliminary source/drain pattern pSD1 may be formed after a portion of the first liner 81 is removed, and the second preliminary source/drain pattern pSD2 may be formed after the first liner 81 is completely removed.

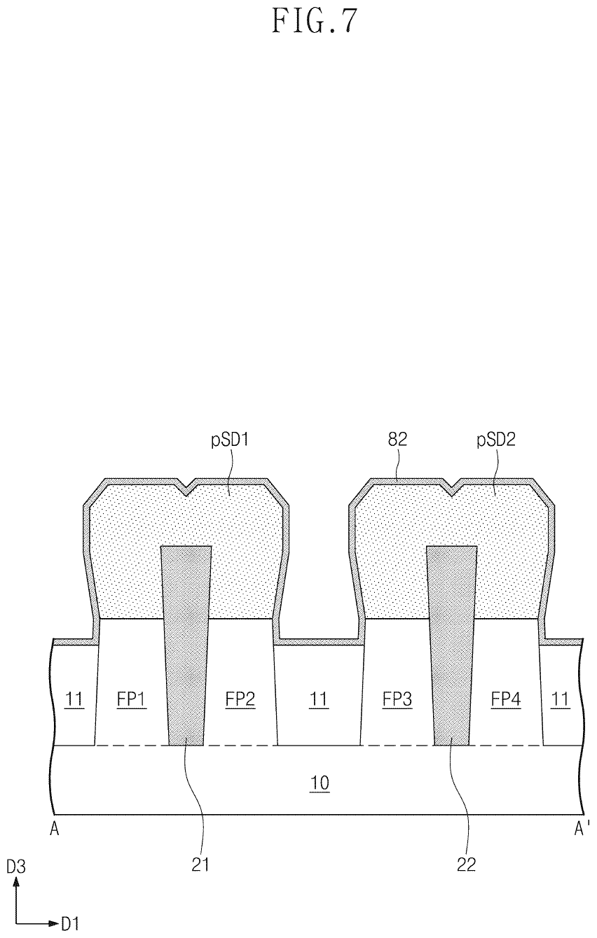

Referring to FIG. 7, a second liner 82 may be formed. The second liner 82 may be formed on the device isolation layer 11 and the first and second preliminary source/drain patterns pSD1 and pSD2. The second liner 82 may include a dielectric material. For example, the second liner 82 may include nitride (e.g., SiCN).

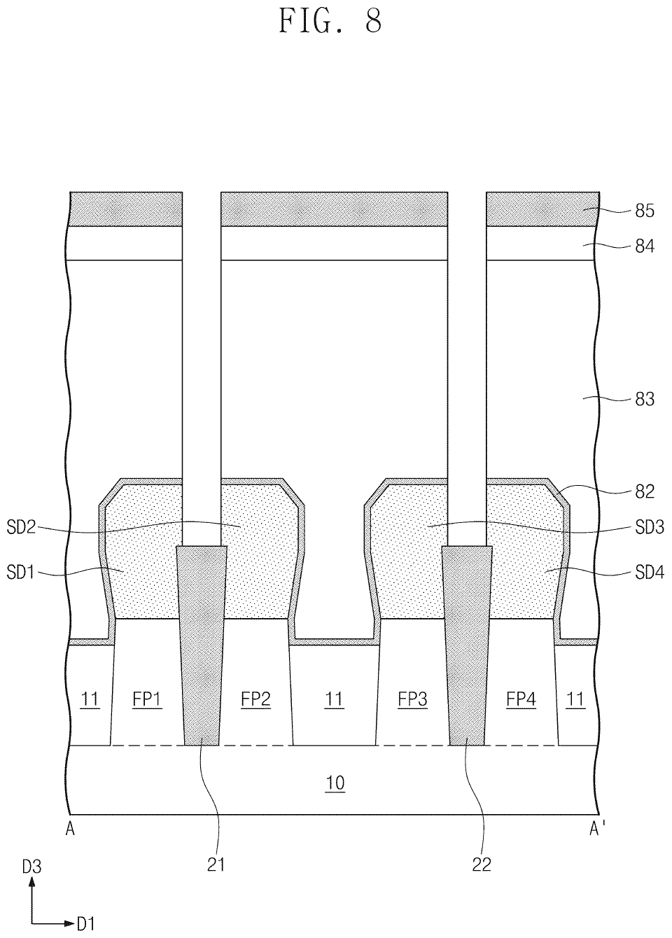

Referring to FIG. 8, a sacrificial layer 83, a mask layer 84, and a photoresist layer 85 may be formed. The sacrificial layer 83 may be formed on the second liner 82. The mask layer 84 may be formed on the sacrificial layer 83. The photoresist layer 85 may be formed on the mask layer 84.

The sacrificial layer 83 may include a dielectric material. For example, the sacrificial layer 83 may include a spin-on-hardmask (SOH) layer. The mask layer 84 may include a dielectric material. The photoresist layer 85 may include a photoresist material.

The photoresist layer 85, the mask layer 84, the sacrificial layer 83, the second liner 82, and the first and second preliminary source/drain patterns pSD1 and pSD2 may be sequentially patterned. The first preliminary source/drain pattern pSD1 may be patterned into a first source/drain pattern SD1 and a second source/drain pattern SD2. The second preliminary source/drain pattern pSD2 may be patterned into a third source/drain pattern SD3 and a fourth source/drain pattern SD4. The first preliminary source/drain pattern pSD1 may be patterned to expose the first lower separation dielectric layer 21. The second preliminary source/drain pattern pSD2 may be patterned to expose the second lower separation dielectric layer 22.

The photoresist layer 85, the mask layer 84, the sacrificial layer 83, and the second liner 82 may be removed during or after the patterning process.

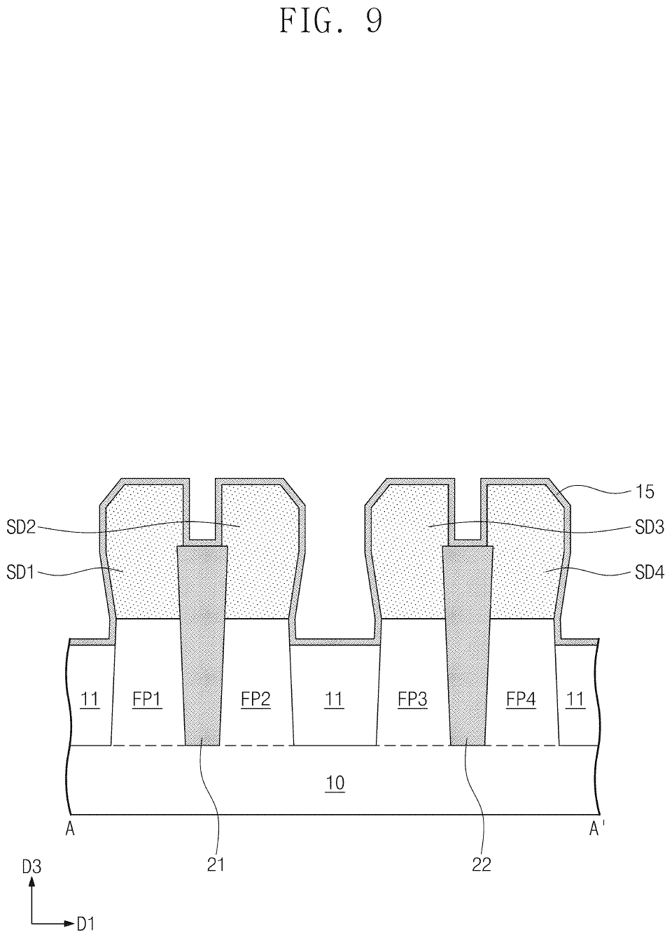

Referring to FIG. 9, a cover dielectric layer 15 may be formed. The cover dielectric layer 15 may be formed on the device isolation layer 11, the source/drain patterns SD1, SD2, SD3, and SD4, and the lower separation dielectric layers 21 and 22.

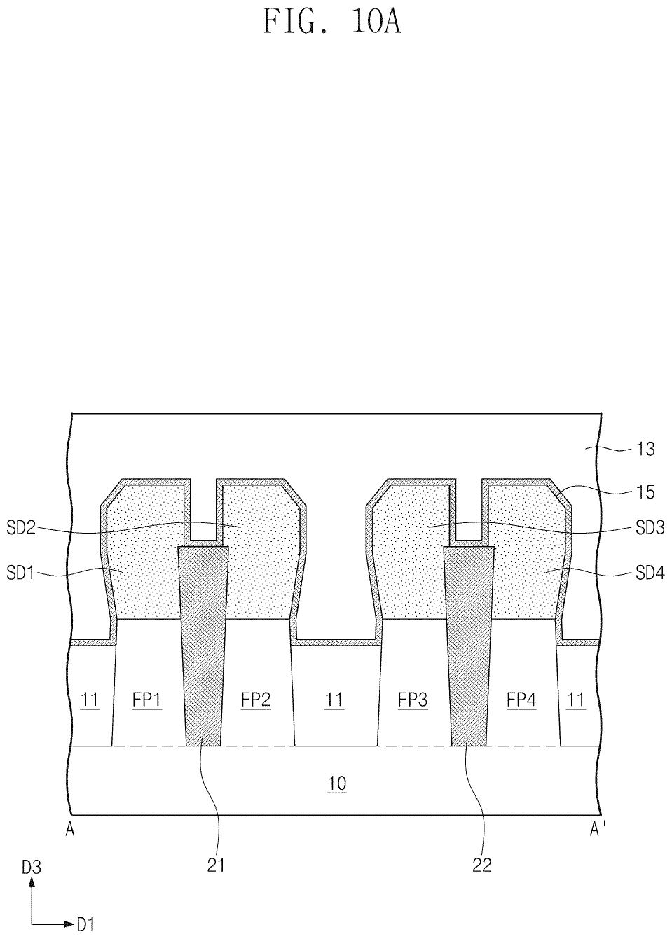

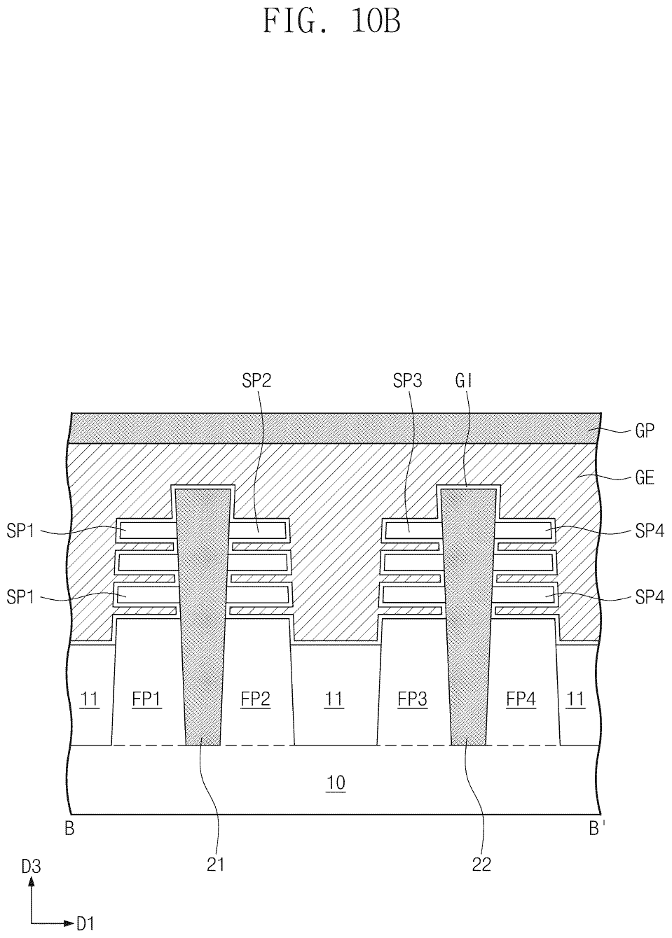

Referring to FIGS. 10A and 10B, an interlayer dielectric layer 13 may be formed on the cover dielectric layer 15. The gate mask pattern 74, the gate sacrificial pattern 73, and the sacrificial semiconductor layers 71 may be removed. A gate dielectric layer GI and a gate electrode GE may be formed. The gate dielectric layer GI and the gate electrode GE may be formed in empty spaces from which the gate sacrificial pattern 73 and the sacrificial semiconductor layers 71 are removed. A gate capping pattern GP may be formed on the gate electrode GE.

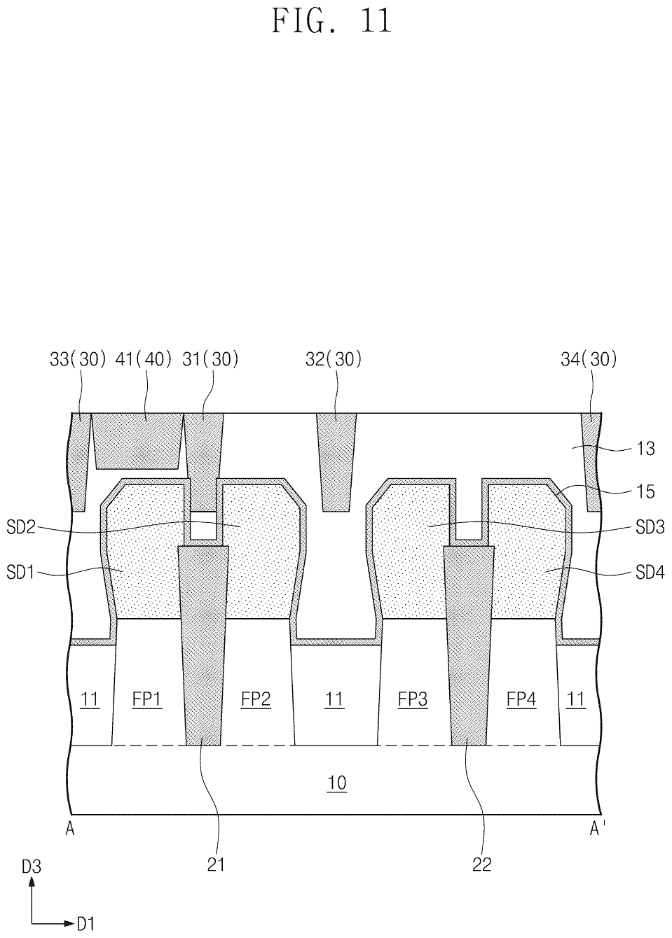

Referring to FIG. 11, upper separation dielectric layers 30 and filling patterns 40 may be formed. The formation of the upper separation dielectric layers 30 and the filling patterns 40 may include etching the interlayer dielectric layer 13, and forming the upper separation dielectric layers 30 and the filling patterns 40 in empty spaces formed by etching the interlayer dielectric layer 13.

In some example embodiments, the upper separation dielectric layers 30 and the filling patterns 40 may be formed simultaneously with each other. In some example embodiments, after the formation of the upper separation dielectric layers 30, the filling patterns 40 may be formed.

The interlayer dielectric layer 13 may be etched to expose a first intervention (see IN1 of FIG. 1E) of the cover dielectric layer 15, and a first dielectric pattern (see IP1 of FIG. 1E) of the interlayer dielectric layer 13 may be formed. The first upper separation dielectric layer 31 may be formed on the first intervention IN1.

Referring to FIGS. 1A to 1D, active contacts AC, merge active contacts MAC, and a gate contact GC may be formed. The formation of the active contacts AC and the merge active contacts MAC may include etching the interlayer dielectric layer 13, and forming the active contacts AC and the merge active contacts MAC in empty spaces formed by etching the interlayer dielectric layer 13.

The interlayer dielectric layer 13 may be etched to form a second dielectric pattern (see IP2 of FIG. 1F) of the interlayer dielectric layer 13.

In a method of fabricating a semiconductor device according to some example embodiments, because there is no upper separation dielectric layer that overlaps the second lower separation dielectric layer 22, there is no need to etch the upper separation dielectric layer in a process for forming the merge active contact MAC, thereby simplifying a fabrication process of the semiconductor device.

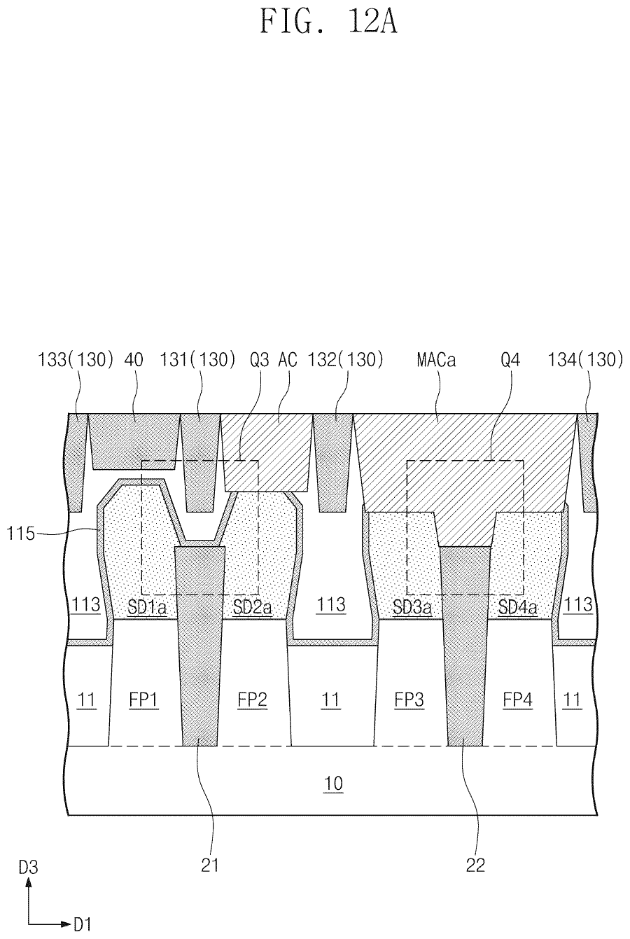

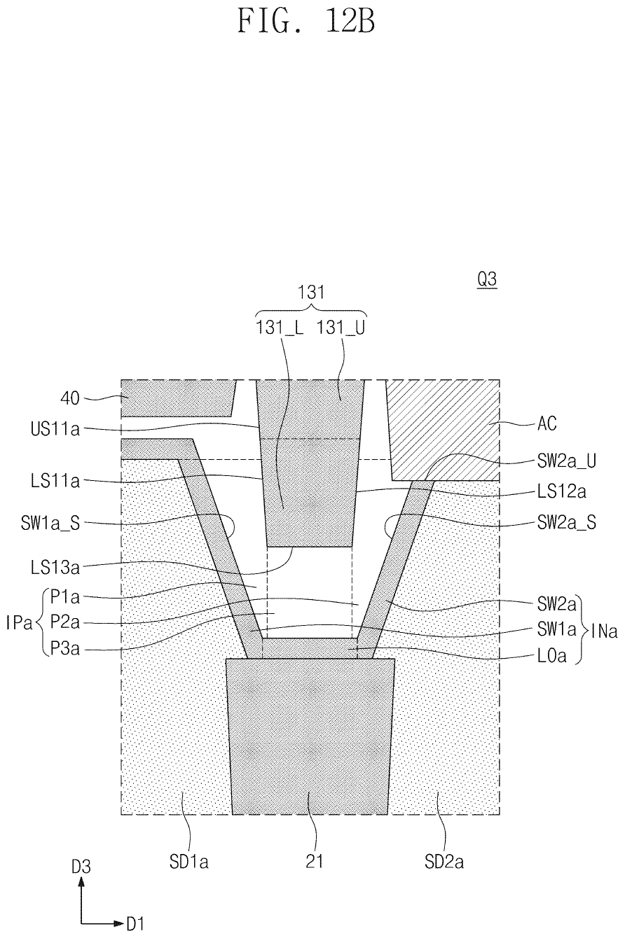

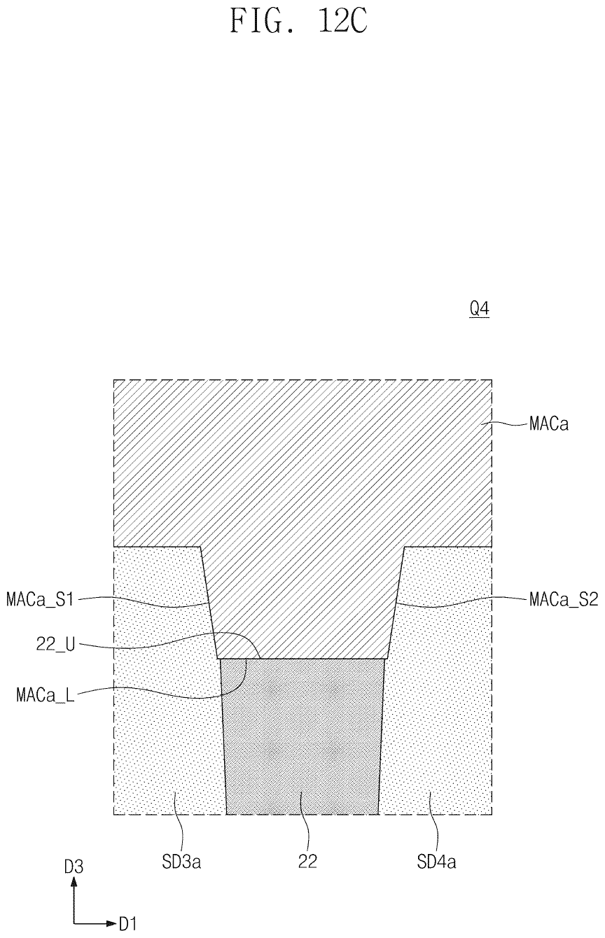

FIG. 12A illustrates a cross-sectional view showing a semiconductor device according to an example embodiment. FIG. 12B illustrates an enlarged view showing section Q3 of FIG. 12A. FIG. 12C illustrates an enlarged view showing section Q4 of FIG. 12A. Except for the following description, a semiconductor device according to FIGS. 12A, 12B, and 12C may be similar to the semiconductor device according to FIGS. 1A to 1F.

Referring to FIGS. 12A and 12B, a cover dielectric layer 115 may be provided on a first source/drain pattern SD1a, a second source/drain pattern SD2a, a third source/drain pattern SD3a, and a fourth source/drain pattern SD4a. An interlayer dielectric layer 113 may be provided on the cover dielectric layer 115.

Upper separation dielectric layers 130 may be provided on the interlayer dielectric layer 113. The upper separation dielectric layers 130 may include a first upper separation dielectric layer 131, a second upper separation dielectric layer 132, a third upper separation dielectric layer 133, and a fourth upper separation dielectric layer 134.

A merge active contact MACa may be provided between the second and fourth upper separation dielectric layers 132 and 134.

The first upper separation dielectric layer 131 may include a lower portion 131_L and an upper portion 131_U. The lower portion 131_L of the first upper separation dielectric layer 131 may be located at a level lower than that of an uppermost portion of the cover dielectric layer 115. The upper portion 131_U of the first upper separation dielectric layer 131 may be located at a level higher than that of the uppermost portion of the cover dielectric layer 115. The upper portion 131_U and the lower portion 131_L of the first upper separation dielectric layer 131 may be spaced apart from the cover dielectric layer 115.

The cover dielectric layer 115 may include an intervention INa between the first source/drain pattern SD1a and the second source/drain pattern SD2a. The first intervention IN1a may include a first sidewall portion SW1a in contact with the first source/drain pattern SD1a, a second sidewall portion SW2a in contact with the second source/drain pattern SD2a, and a lower portion LOa that connects the first sidewall portion SW1a and the second sidewall portion SW2a to each other.

The interlayer dielectric layer 113 may include a dielectric pattern IPa between the first source/drain pattern SD1a and the second source/drain pattern SD2a. The dielectric pattern IPa may include a first portion P1a between the first sidewall portion SW1a and the lower portion 131_L of the first upper separation dielectric layer 131, a second portion P2a between the second sidewall portion SW2a and the lower portion 131_L of the first upper separation dielectric layer 131, and a third portion P3a that connects the first portion P1a and the second portion P2a to each other. The third portion P3a of the dielectric pattern IPa may be disposed between the lower portion 131_L of the first upper separation dielectric layer 131 and the lower portion LOa of the intervention INa.

A first sidewall LS11a of the lower portion 131_L included in the first upper separation dielectric layer 131 may be spaced apart from a sidewall SW1a_S of the first sidewall portion SW1a. The first sidewall LS11a of the lower portion 131_L of the first upper separation dielectric layer 131 and the sidewall SW1a_S of the first sidewall portion SW1a may be in contact with the first portion P1a of the dielectric pattern IPa. A second sidewall LS12a of the lower portion 131_L of the first upper separation dielectric layer 131 may be spaced apart from a sidewall SW2a_S of the second sidewall portion SW2a. The second sidewall LS12a of the lower portion 131_L of the first upper separation dielectric layer 131 and the sidewall SW2a_S of the second sidewall portion SW2a may be in contact with the second portion P2a of the dielectric pattern IPa. A bottom surface LS13a of the lower portion 131_L of the first upper separation dielectric layer 131 may be in contact with the third portion P3a of the dielectric pattern IPa.

A sidewall US11a of the upper portion 131_U of the first upper separation dielectric layer 131 may be spaced apart from the cover dielectric layer 115. The sidewall US11a of the upper portion 131_U of the first upper separation dielectric layer 131 may be in contact with the interlayer dielectric layer 113. The sidewall US11a of the upper portion 131_U of the first upper separation dielectric layer 131 may be located at a level higher than that of an uppermost portion of the cover dielectric layer 115. The sidewall US11a of the upper portion 131_U of the first upper separation dielectric layer 131 may be coplanar with the sidewalls LS11a and LS12a of the lower portion 131_L of the first upper separation dielectric layer 131.

A top surface SW2a_U of the second sidewall portion SW2a may be in contact with the active contact AC.

In some example embodiments, an air gap may be provided between the first sidewall portion SW1a and the second sidewall SW2a of the intervention INa.

Referring to FIG. 12C, a bottom surface MACa_L of the merge active contact MACa may be in contact with a top surface 22_U of the second lower separation dielectric layer 22. The merge active contact MACa may include a first sidewall MACa_S1 and a second sidewall MACa_S2 that are connected to the bottom surface MACa_L. The first sidewall MACa_S1 of the merge active contact MACa may be in contact with the third source/drain pattern SD3a. The second sidewall MACa_S2 of the merge active contact MACa may be in contact with the fourth source/drain pattern SD4a.

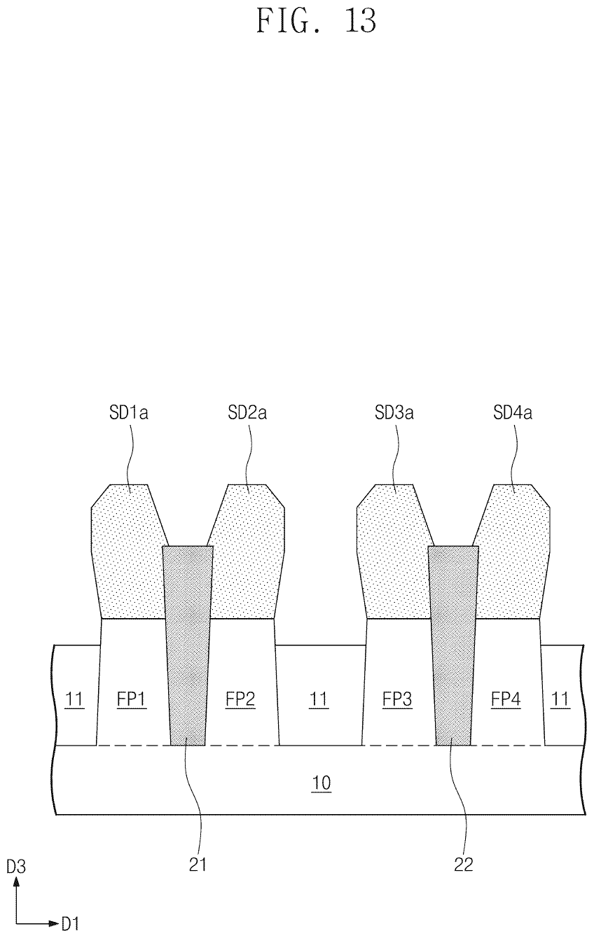

FIGS. 13, 14, 15, and 16 illustrate cross-sectional views showing a method of fabricating a semiconductor device according to FIGS. 12A to 12C.

Referring to FIG. 13, similar to that discussed in FIGS. 2 to 5, a substrate 10 including fin patterns FP1, FP2, FP3, and FP4, a device isolation layer 11, and first and second lower separation dielectric layers 21 and 22 may be formed.

First, second, third, and fourth source/drain patterns SD1a, SD2a, SD3a, and SD4a may be formed through a vertical epitaxial growth process. The vertical epitaxial growth process may be a growth process that suppresses lateral growth. As the first, second, third, and fourth source/drain patterns SD1a, SD2a, SD3a, and SD4a are formed through the vertical epitaxial growth process, the first and second source/drain patterns SD1a and SD2a may be spaced apart from each other without being merged, and the third and fourth source/drain patterns SD3a and SD4a may be spaced apart from each other without being merged.

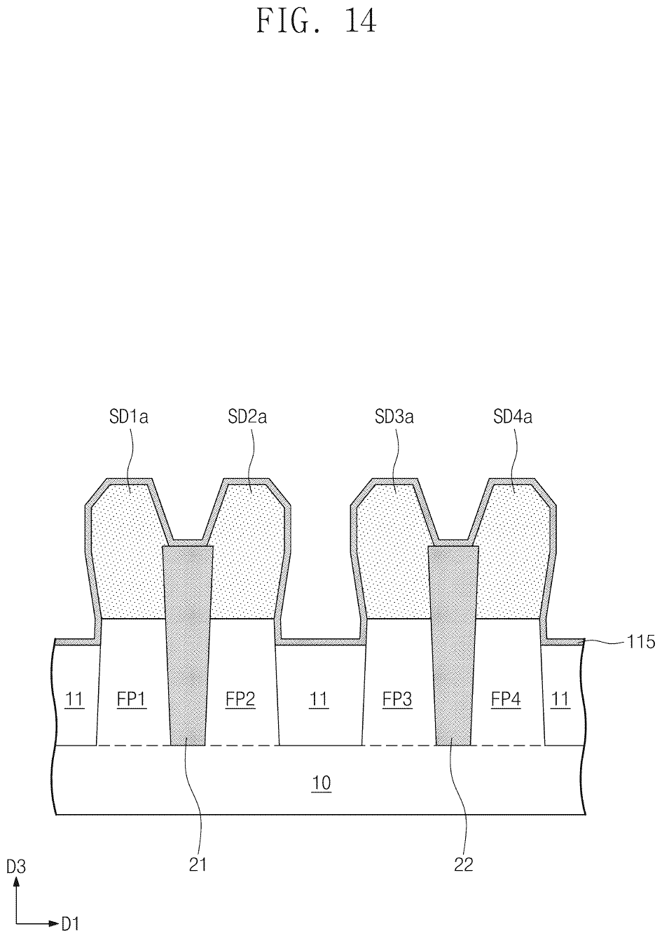

Referring to FIG. 14, a cover dielectric layer 115 may be formed. The cover dielectric layer 115 may be formed on the device isolation layer 11, the source/drain patterns SD1a, SD2a, SD3a, and SD4a, and the lower separation dielectric layers 21 and 22.

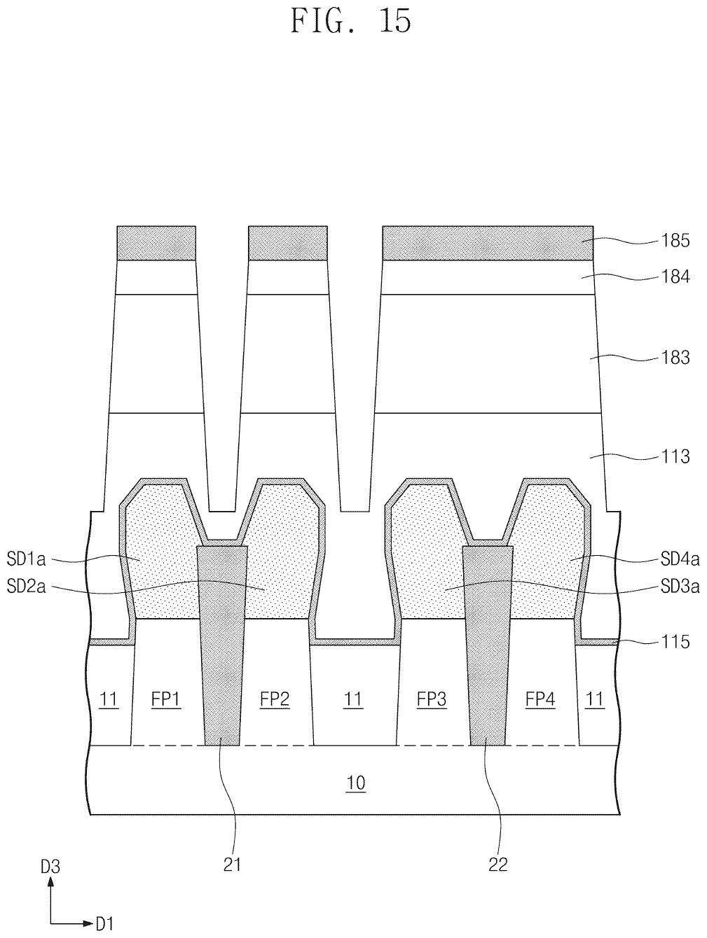

Referring to FIG. 15, an interlayer dielectric layer 113 may be formed on the cover dielectric layer 115. A sacrificial layer 183, a mask layer 184, and a photoresist layer 185 may be formed on the interlayer dielectric layer 113.

The photoresist layer 185, the mask layer 184, the sacrificial layer 183, and the interlayer dielectric layer 113 may be sequentially patterned. The photoresist layer 185, the mask layer 184, and the sacrificial layer 183 may be removed during or after the patterning process.

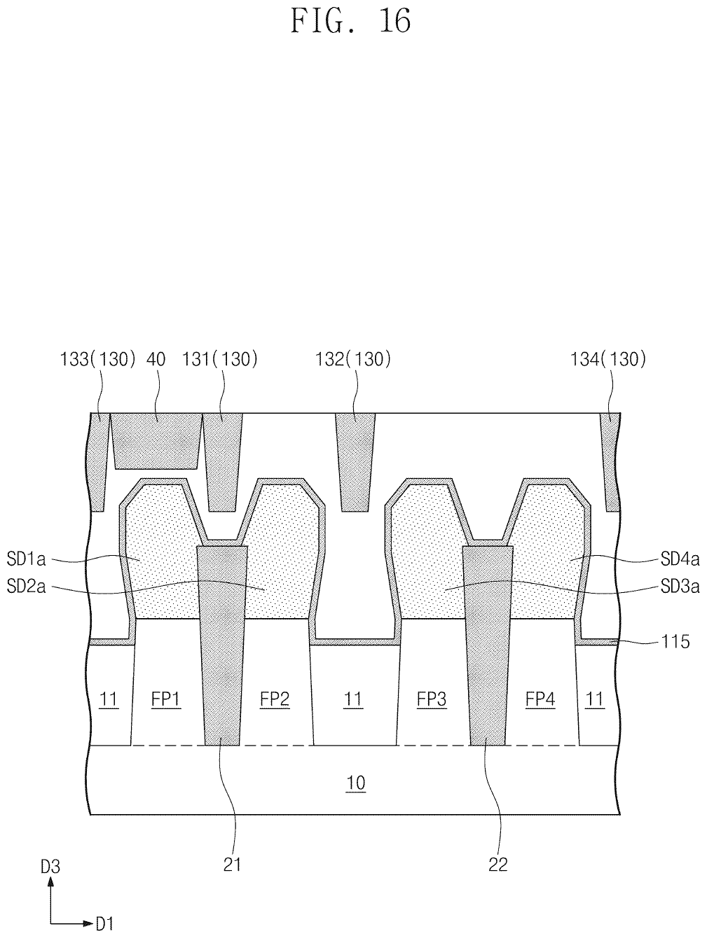

Referring to FIG. 16, upper separation dielectric layers 130 and a filling pattern 40 may be formed. The formation of the upper separation dielectric layers 130 may include forming the upper separation dielectric layers 130 in empty spaces formed by patterning the interlayer dielectric layer 113.

Referring to FIG. 12A, an active contact AC and a merge active contact MACa may be formed.

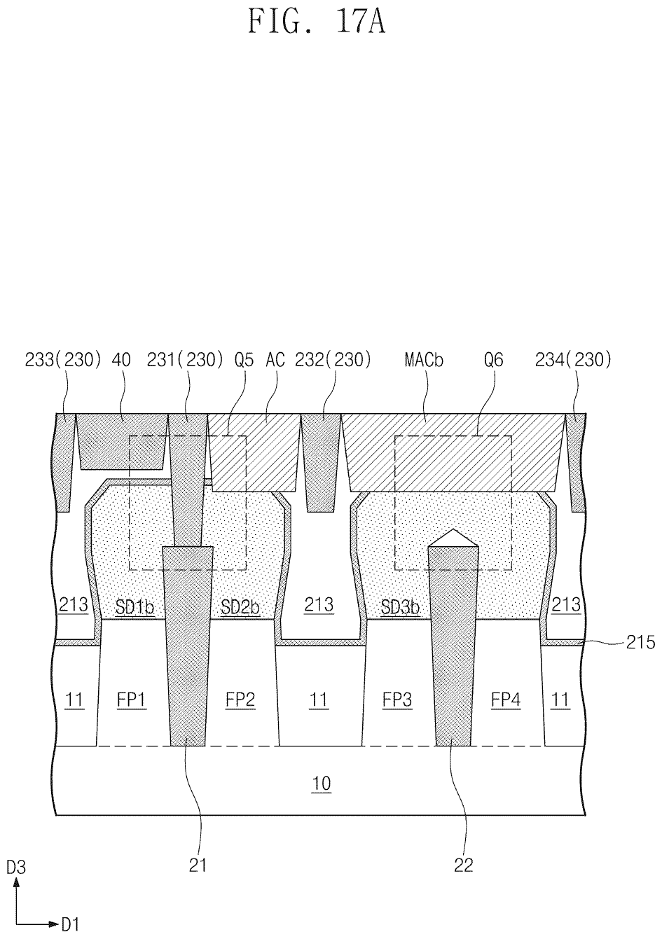

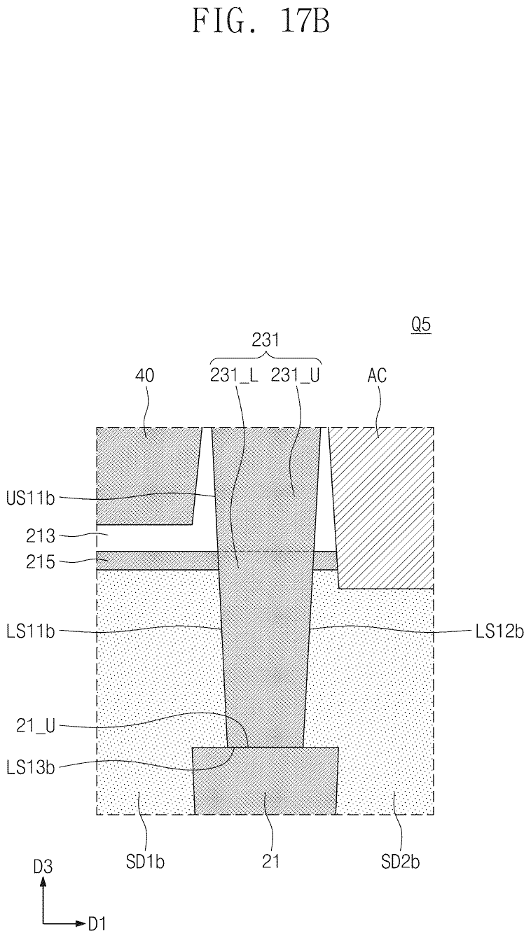

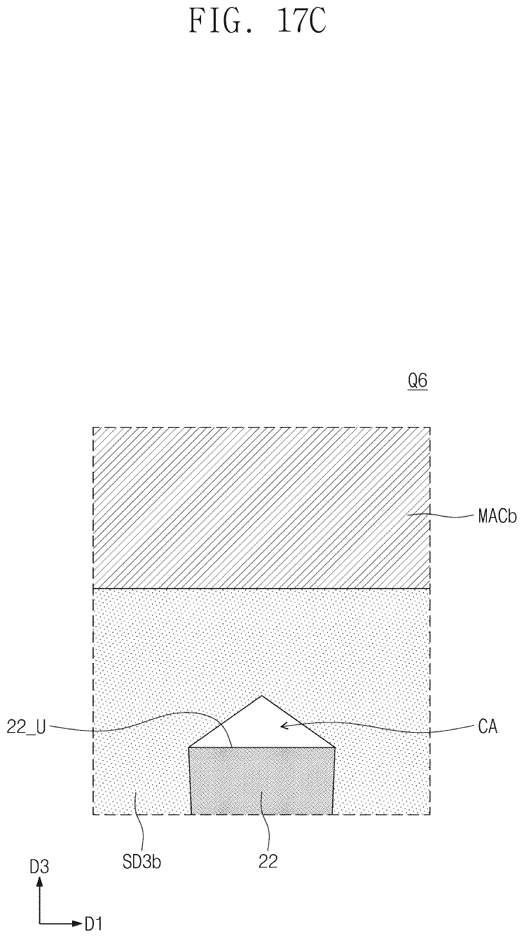

FIG. 17A illustrates a cross-sectional view showing a semiconductor device according to an example embodiment. FIG. 17B illustrates an enlarged view showing section Q5 of FIG. 17A. FIG. 17C illustrates an enlarged view showing section Q6 of FIG. 17A. Except for the following description, a semiconductor device according to FIGS. 17A to 17C may be similar to the semiconductor device according to FIGS. 1A to 1F.

Referring to FIGS. 17A and 17B, a first source/drain pattern SD1b, a second source/drain pattern SD2b, and a merge source/drain pattern SD3b may be provided. The first source/drain pattern SD1b may overlap in the third direction D3 the first fin pattern FP1. The second source/drain pattern SD2b may overlap in the third direction D3 the second fin pattern FP2. The merge source/drain pattern SD3b may overlap in the third direction D3 the third and fourth fin patterns FP3 and FP4 and the second lower separation dielectric layer 22.

A cover dielectric layer 215 may be provided on the first source/drain pattern SD1b, the second source/drain pattern SD2b, and the merge source/drain pattern SD3b. An interlayer dielectric layer 213 may be provided on the cover dielectric layer 215.

Upper separation dielectric layers 230 may be provided on the interlayer dielectric layer 213. The upper separation dielectric layers 230 may include a first upper separation dielectric layer 231, a second upper separation dielectric layer 232, a third upper separation dielectric layer 233, and a fourth upper separation dielectric layer 234. The first upper separation dielectric layer 231 may overlap in the third direction D3 the first lower separation dielectric layer 21. A length in the third direction D3 of the first upper separation dielectric layer 231 may be greater than a length in the third direction D3 of the second, third, and fourth upper separation dielectric layers 232, 233, and 234.

The merge active contact MACb may be provided between the second and fourth upper separation dielectric layers 232 and 234.

The first upper separation dielectric layer 231 may include a lower portion 231_L and an upper portion 231_U. The lower portion 231_L of the first upper separation dielectric layer 231 may be located at a level lower than that of an uppermost portion of the cover dielectric layer 215. The upper portion 231_U of the first upper separation dielectric layer 231 may be located at a level higher than that of the uppermost portion of the cover dielectric layer 215.

A first sidewall LS11b of the lower portion 231_L of the first upper separation dielectric layer 231 may be in contact with the first source/drain pattern SD1b. A second sidewall LS12b of the lower portion 231_L of the first upper separation dielectric layer 231 may be in contact with the second source/drain pattern SD2b. A bottom surface LS13b of the lower portion 231_L of the first upper separation dielectric layer 231 may be in contact with a top surface 21_U of the first lower separation dielectric layer 21.

A sidewall US11b of the upper portion 231_U of the first upper separation dielectric layer 231 may be spaced apart from the cover dielectric layer 215. The sidewall US11b of the upper portion 231_U of the first upper separation dielectric layer 231 may be in contact with the interlayer dielectric layer 213. The sidewall US11b of the upper portion 231_U of the first upper separation dielectric layer 231 may be located at a level higher than that of the uppermost portion of the cover dielectric layer 215. The sidewall US11b of the upper portion 231_U of the first upper separation dielectric layer 231 may be coplanar with the sidewalls LS11b and LS12b of the lower portion 231_L.

Referring to FIG. 17C, the merge active contact MACb may be in contact with the merge source/drain pattern SD3b. A cavity CA may be provided between the merge source/drain pattern SD3b and the second lower separation dielectric layer 22. The cavity CA may be an empty space. In some example embodiments, a gas may be provided in the cavity CA. A top surface 22_U of the second lower separation dielectric layer 22 may be exposed through the cavity CA. A surface of the merge source/drain pattern SD3b may be exposed through the cavity CA.

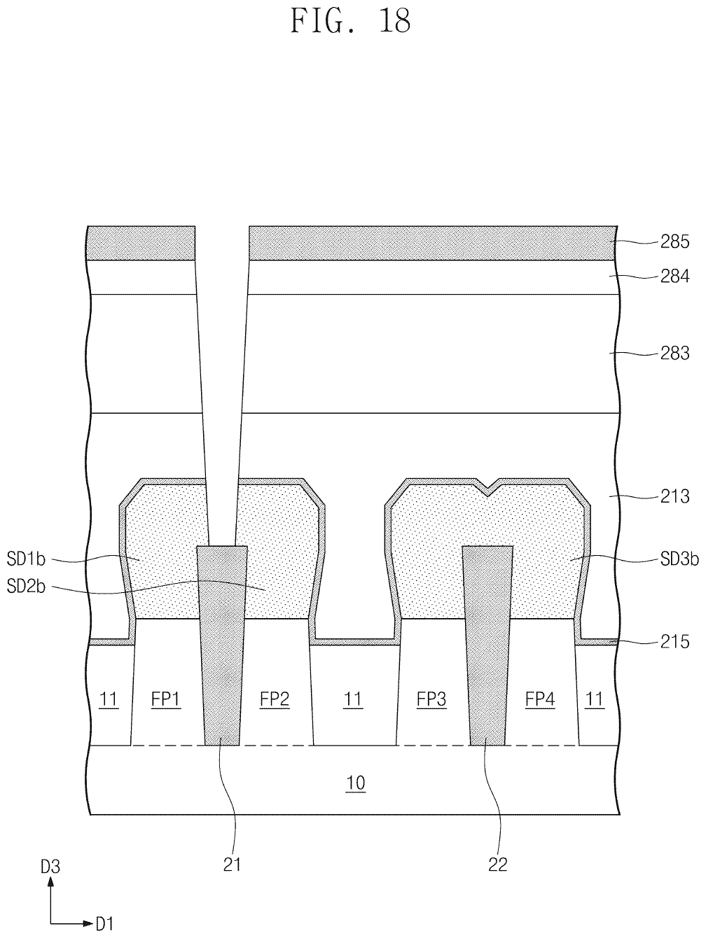

FIGS. 18, 19, and 20 illustrate cross-sectional views showing a method of fabricating a semiconductor device according to FIGS. 17A to 17C.

Referring to FIG. 18, similar to that discussed in FIGS. 2 to 5, there may be formed a substrate 10 including fin patterns FP1, FP2, FP3, and FP4, a device isolation layer 11, and first and second lower separation dielectric layers 21 and 22. A preliminary merge source/drain pattern may be formed on the first and second fin patterns FP1 and FP2. A merge source/drain pattern SD3b may be formed on the third and fourth fin patterns FP3 and FP4. The preliminary merge source/drain pattern may have a shape similar to that of the merge source/drain pattern SD3b.

A cover dielectric layer 215 may be formed on the preliminary merge source/drain pattern and the merge source/drain pattern SD3b. An interlayer dielectric layer 213 may be formed on the cover dielectric layer 215. A sacrificial layer 283, a mask layer 284, and a photoresist layer 285 may be formed on the interlayer dielectric layer 213.

A first patterning process may be performed to sequentially pattern the photoresist layer 285, the mask layer 284, the sacrificial layer 283, the interlayer dielectric layer 213, the cover dielectric layer 215, and the preliminary merge source/drain pattern.

The first patterning process may separate the preliminary merge source/drain pattern into a first source/drain pattern SD1b and a second source/drain pattern SD2b.

The photoresist layer 285, the mask layer 284, and the sacrificial layer 283 may be removed during or after the first patterning process.

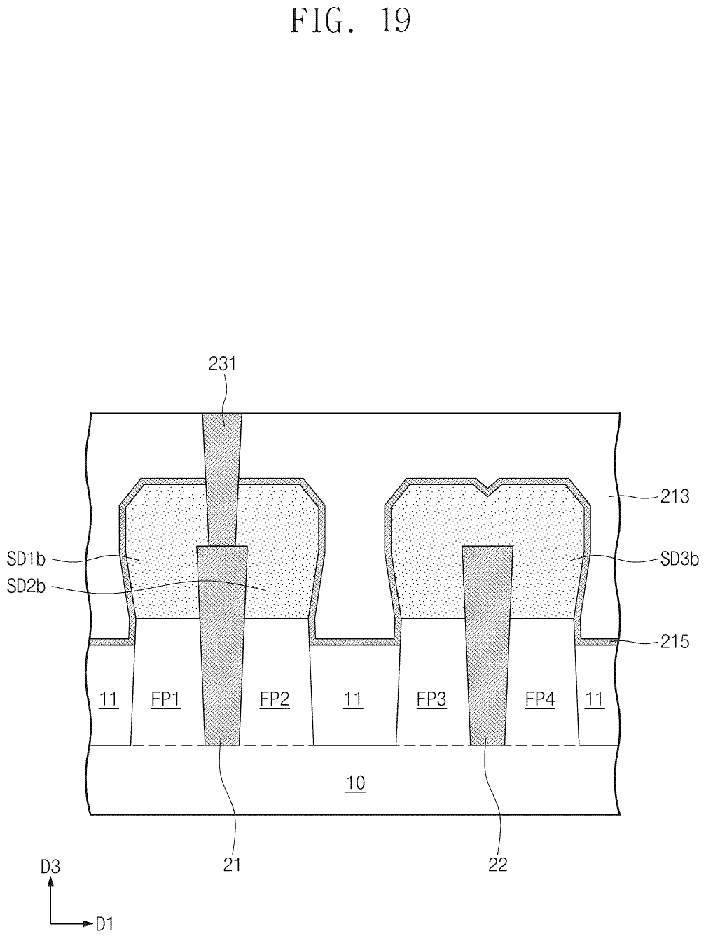

Referring to FIG. 19, a first upper separation dielectric layer 231 may be formed. The formation of the first upper separation dielectric layer 231 may include forming the first upper separation dielectric layer 231 in an empty space formed by the first patterning process that patterns the interlayer dielectric layer 213.

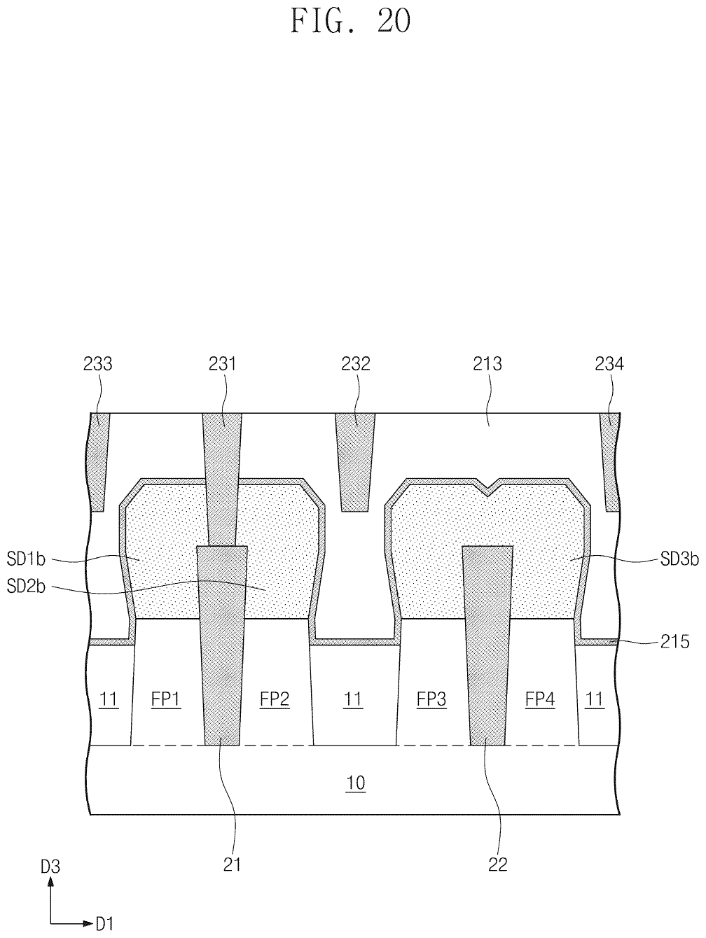

Referring to FIG. 20, second, third, and fourth upper separation dielectric layers 232, 233, and 234 may be formed. The formation of the second, third, and fourth upper separation dielectric layers 232, 233, and 234 may include performing a second patterning process that patterns the interlayer dielectric layer 213, and forming the second, third, and fourth upper separation dielectric layers 232, 233, and 234 in empty spaces formed by the second patterning process.

Referring to FIG. 17A, an active contact AC and a merge active contact MACb may be formed.

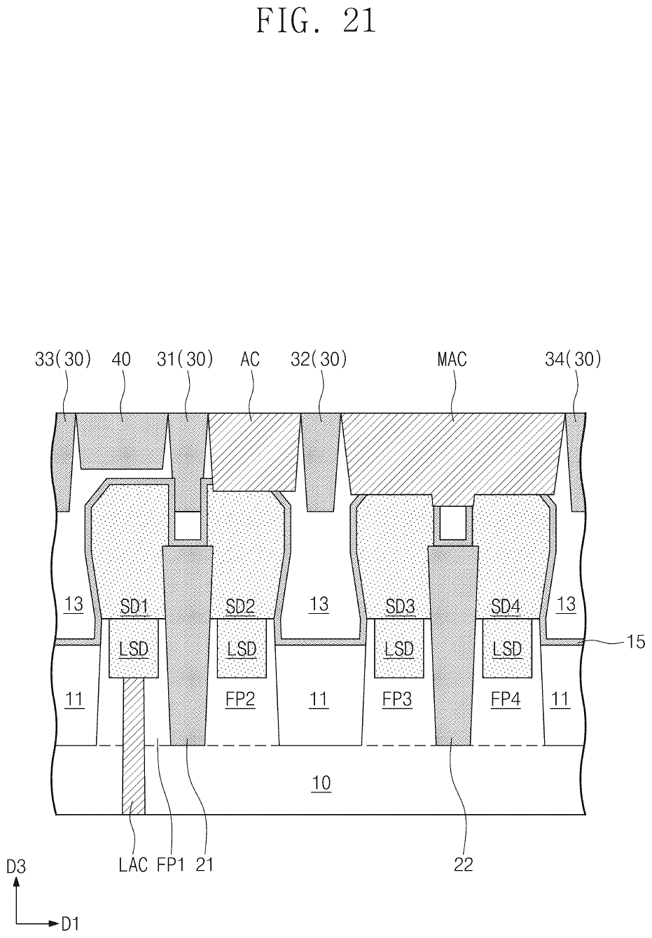

FIG. 21 illustrates a cross-sectional view showing a semiconductor device according to an example embodiment. Except for the following description, a semiconductor device of FIG. 21 may be similar to the semiconductor device of FIGS. 1A to 2F.

Referring to FIG. 21, a semiconductor device may include lower source/drain patterns LSD. The lower source/drain patterns LSD may be disposed underneath the source/drain patterns SD1, SD2, SD3, and SD4, respectively. The lower source/drain patterns LSD may be disposed on the fin patterns FP1, FP2, FP3, and FP4, respectively.

The lower source/drain patterns LSD may be an epitaxial pattern formed by a selective epitaxial growth process. The lower source/drain patterns LSD may include, for example, silicon (Si) or silicon-germanium (SiGe).

The semiconductor device may include a lower active contact LAC. The lower active contact LAC may penetrate the substrate 10 and the first fin pattern FP1 to come into connection with the lower source/drain pattern LSD. The lower active contact LAC may include a conductive material.

In a semiconductor device according to some example embodiment of the present inventive concepts, an air gap is provided between source/drain patterns, the air gap may reduce capacitance.

In a semiconductor device according to some example embodiment of the present inventive concepts, an upper separation dielectric layer is not disposed between source/drain patterns connected to a merge active contact, and thus contact resistance of the merge active contact may be reduced.

Although some example embodiments of the present inventive concepts have been discussed with reference to accompanying figures, it will be understood that various changes in form and details may be made therein without departing from the spirit and scope of the present inventive concepts. It therefore will be understood that the example embodiments described above are just illustrative but not limitative in all aspects.

What is claimed is

1. A semiconductor device, comprising:
a first fin pattern and a second fin pattern;
a first source/drain pattern overlapping the first fin pattern;
a second source/drain pattern overlapping the second fin pattern;
a lower separation dielectric layer between the first and second fin patterns and between the first and second source/drain patterns;
a cover dielectric layer on the first source/drain pattern and the second source/drain pattern; and
an upper separation dielectric layer overlapping the lower separation dielectric layer,
wherein a lower portion of the upper separation dielectric layer is between the first source/drain pattern and the second source/drain pattern, and
wherein an upper portion of the upper separation dielectric layer is at a level higher than a level of the cover dielectric layer.

2. The semiconductor device of claim 1, wherein
the cover dielectric layer comprises an intervention between the first source/drain pattern and the second source/drain pattern, and
a sidewall of the lower portion of the upper separation dielectric layer is in contact with the intervention of the cover dielectric layer.

3. The semiconductor device of claim 2, wherein the intervention comprises:
a first sidewall portion in contact with the first source/drain pattern;
a second sidewall portion in contact with the second source/drain pattern; and
a lower portion connected to the first sidewall portion and the second sidewall portion,
wherein the semiconductor device further comprises a dielectric pattern between the first and second sidewall portions and between the lower portion of the intervention and the lower portion of the upper separation dielectric layer.

4. The semiconductor device of claim 3, wherein the dielectric pattern includes an air gap.

5. The semiconductor device of claim 1, wherein
the cover dielectric layer comprises an intervention between the first source/drain pattern and the second source/drain pattern, and
a first sidewall of the lower portion of the upper separation dielectric layer and a second sidewall opposite to the first sidewall are spaced apart from the intervention of the cover dielectric layer.

6. The semiconductor device of claim 5, further comprising:
an interlayer dielectric layer on the cover dielectric layer,
wherein the interlayer dielectric layer comprises a dielectric pattern between the first source/drain pattern and the second source/drain pattern, and
wherein the first sidewall, the second sidewall, and a bottom surface of the lower portion of the upper separation dielectric layer are in contact with the dielectric pattern.

7. The semiconductor device of claim 6, wherein the intervention comprises:
a first sidewall portion in contact with the first source/drain pattern;
a second sidewall portion in contact with the second source/drain pattern; and
a lower portion connected to the first sidewall portion and the second sidewall portion,
wherein the dielectric pattern comprises:
a first portion between the first sidewall of the lower portion of the upper separation dielectric layer and the first sidewall portion of the intervention;
a second portion between the second sidewall of the lower portion of the upper separation dielectric layer and the second sidewall portion of the intervention; and
a third portion that connects the first portion and the second portion to each other,
wherein the third portion of the dielectric pattern is between the bottom surface of the lower portion of the upper separation dielectric layer and the lower portion of the intervention.

8. The semiconductor device of claim 1, wherein the lower portion of the upper separation dielectric layer is in contact with the first source/drain pattern and the second source/drain pattern.

9. A semiconductor device, comprising:
a first fin pattern and a second fin pattern;
a first source/drain pattern overlapping the first fin pattern;
a second source/drain pattern overlapping the second fin pattern;
a first lower separation dielectric layer between the first and second fin patterns and between the first and second source/drain patterns;
a cover dielectric layer on the first source/drain pattern and the second source/drain pattern;
an interlayer dielectric layer on the cover dielectric layer; and
an upper separation dielectric layer overlapping the first lower separation dielectric layer,
wherein a lower portion of the upper separation dielectric layer is between the first source/drain pattern and the second source/drain pattern, and
wherein a sidewall of an upper portion of the upper separation dielectric layer is in contact with the interlayer dielectric layer.

10. The semiconductor device of claim 9, further comprising:
a third fin pattern;
a fourth fin pattern spaced apart from the third fin pattern;
a second lower separation dielectric layer between the third fin pattern and the fourth fin pattern;
a third source/drain pattern overlapping the third fin pattern;
a fourth source/drain pattern overlapping the fourth fin pattern; and
a merge active contact in contact with the third source/drain pattern and the fourth source/drain pattern,
wherein the cover dielectric layer comprises an intervention between the merge active contact and the second lower separation dielectric layer and between the third and fourth source/drain patterns.

11. The semiconductor device of claim 10, further comprising:
a dielectric pattern between the merge active contact and the intervention.

12. The semiconductor device of claim 9, further comprising:
a third fin pattern;
a fourth fin pattern spaced apart from the third fin pattern;
a second lower separation dielectric layer between the third fin pattern and the fourth fin pattern;
a third source/drain pattern overlapping the third fin pattern;
a fourth source/drain pattern overlapping the fourth fin pattern; and
a merge active contact in contact with the third source/drain pattern, the fourth source/drain pattern, and the second lower separation dielectric layer.

13. The semiconductor device of claim 9, further comprising:
a third fin pattern;
a fourth fin pattern spaced apart from the third fin pattern;
a second lower separation dielectric layer between the third fin pattern and the fourth fin pattern;
a merge source/drain pattern overlapping the third fin pattern, the fourth fin pattern, and the second lower separation dielectric layer; and
a merge active contact in contact with the merge source/drain pattern.

14. The semiconductor device of claim 9, wherein the lower portion of the upper separation dielectric layer is in contact with the first source/drain pattern, the second source/drain pattern, the first lower separation dielectric layer, and the cover dielectric layer.

15. The semiconductor device of claim 9, wherein
the cover dielectric layer comprises an intervention between the first source/drain pattern and the second source/drain pattern, and
the intervention comprises
a first sidewall portion in contact with the first source/drain pattern,
a second sidewall portion in contact with the second source/drain pattern, and
a lower portion connecting the first sidewall portion to the second sidewall portion, and
wherein the lower portion of the intervention is in contact with a top surface of the first lower separation dielectric layer.

16. The semiconductor device of claim 15, wherein the lower portion of the upper separation dielectric layer comprises:
a first sidewall in contact with the first sidewall portion of the intervention; and
a second sidewall in contact with the second sidewall portion of the intervention.

17. The semiconductor device of claim 15, wherein
the lower portion of the upper separation dielectric layer comprises a first sidewall and a second sidewall that are in contact with the interlayer dielectric layer, and
the first sidewall and the second sidewall of the lower portion of the upper separation dielectric layer are opposite to each other.

18. A semiconductor device, comprising:
a first fin pattern and a second fin pattern;
a plurality of first semiconductor patterns overlapping the first fin pattern;
a plurality of second semiconductor patterns overlapping the second fin pattern;
a first source/drain pattern connected to the first semiconductor patterns;
a second source/drain pattern connected to the second semiconductor patterns;
a gate electrode overlapping the first semiconductor patterns;
a first lower separation dielectric layer between the first and second fin patterns, between the first and second semiconductor patterns, and between the first and second source/drain patterns;
a first upper separation dielectric layer overlapping the first lower separation dielectric layer;
an active contact connected to the second source/drain pattern;
a third fin pattern and a fourth fin pattern spaced apart from the first and second fin patterns;
a plurality of third semiconductor patterns overlapping the third fin pattern;
a plurality of fourth semiconductor patterns overlapping the fourth fin pattern;
a second lower separation dielectric layer between the third and fourth fin patterns and between the third and fourth semiconductor patterns;
a merge active contact overlapping the second lower separation dielectric layer, the third fin pattern, and the fourth fin pattern;
a second upper separation dielectric layer between the merge active contact and the active contact;
a cover dielectric layer in contact with the active contact, the merge active contact, and the first and second source/drain patterns; and
an interlayer dielectric layer on the cover dielectric layer,
wherein an upper portion of the first upper separation dielectric layer has a sidewall spaced apart from the cover dielectric layer.

19. The semiconductor device of claim 18, further comprising:
an air gap between the first upper separation dielectric layer and the first lower separation dielectric layer.

20. The semiconductor device of claim 18, wherein a lower portion of the first upper separation dielectric layer is spaced apart from the cover dielectric layer.
